(19) United States
(12) Patent Application Publication
(10) Pub. No.: US 2023/0307577 A1
(43) Pub. Date: Sep. 28, 2023

(54) DISPLAY DEVICE AND MANUFACTURING METHOD THEREFOR

(71) Applicant: SAMSUNG DISPLAY CO., LTD., Yongin-si, Gyeonggi-do (KR)

(72) Inventors: Hyun Sup LEE, Yongin-si, Gyeonggi-do (KR); SUNG-CHAN JO, Yongin-si, Gyeonggi-do (KR)

(73) Assignee: SAMSUNG DISPLAY CO., LTD., Yongin-si, Gyeonggi-do (KR)

(21) Appl. No.: 17/928,647

(22) PCT Filed: Oct. 19, 2020
(86) PCT No.: PCT/KR2020/014277

§ 371 Date: Nov. 30, 2022

(30) Foreign Application Priority Data
Jun. 1, 2020 (KR) 10-2020-0066095

(51) Int. Cl. H01L 33/24; H01L 25/075; H01L 33/62; H01L 33/38; H01L 25/16; H01L 27/12

(52) U.S. Cl. CPC H01L 33/24; H01L 25/0753; H01L 33/62; H01L 33/38; H01L 25/167; H01L 27/1218; H01L 2933/0016; H01L 2933/0066

(57) ABSTRACT

A display device and a manufacturing method thereof are provided. A display device according to an embodiment includes a substrate including a first emission area, and a first light emitting element disposed on the substrate and emitting light of a first color. The substrate further includes a first hole passing through the substrate in the first emission area, and at least a portion of the first light emitting element is arranged in the first hole.

### CROSS-REFERENCE TO RELATED APPLICATION(S)

This application is a national entry of International Application No. PCT/KR2020/014277, filed on Oct. 19, 2020, which claims under 35 U.S.C. §§ 119(a) and 365(b) priority to and benefits of Korean Patent Application No. 10-2020-0066095, filed on Jun. 1, 2020, in the Korean Intellectual Property Office (KIPO), the entire contents of which are incorporated herein by reference.

### BACKGROUND

### 1. Technical Field

The disclosure relates to a display device and a method of manufacturing the same.

### 2. Description of the Related Art

In recent years, interest in information display has increased. Accordingly, research and development on a display device is continuously performed.

### SUMMARY

An object to be achieved by the disclosure is to provide a display device and a method of manufacturing the same capable of aligning and fixing a light emitting element in a vertical direction according to a pressure difference of a substrate including a through hole.

Objects of the disclosure are not limited to the above-described object, and other technical objects which are not described will be clearly understood by those skilled in the art from the following description.

### Technical Solution

According to an embodiment of the disclosure for achieving the above-described object, a display device may include a substrate including a first emission area, and a first light emitting element disposed on the substrate and emitting light of a first color. The substrate may further include a first hole passing through the substrate in the first emission area, and at least a portion of the first light emitting element may be disposed in the first hole.

The first light emitting element may include a first surface and a second surface opposite to each other, the first surface may be disposed adjacent to a lower surface of the substrate, the second surface may be disposed adjacent to an upper surface of the substrate, and an aspect ratio of the first light emitting element may be greater than 1.

A diameter of the second surface may be greater than a diameter of the first surface, and the first light emitting element may further include a side surface disposed between the first surface and the second is surface.

The side surface of the first light emitting element may contact an inner circumferential surface of the first hole.

The substrate may include a sidewall in the first hole, the sidewall being perpendicular to the lower surface of the substrate, a diameter of the first hole may be greater than the diameter of the first surface, and the diameter of the first hole may be less than the diameter of the second surface, and a portion of the first light emitting element may protrude to an outside of the substrate.

The display device may further include a filler filling a space between the sidewall and the first light emitting element.

The substrate may include a sidewall in first hole, the sidewall may include a vertical surface perpendicular to the lower surface of the substrate and an inclined surface having an angle with respect to the lower surface of the substrate, the side surface of the first light emitting element may contact the inclined surface, and the side surface of the first light emitting element does not contact the vertical surface.

A diameter of the first surface and a diameter of the second surface may be the same in a plan view.

The substrate may include a sidewall in the first hole, the sidewall having an angle with respect to the lower surface of the substrate, a diameter of the first light emitting element may be greater than a diameter of and the first hole on the lower surface of the substrate, the diameter of the first light emitting element may be less than a diameter of the first hole on the upper surface of the substrate, and a portion of the first light emitting element may protrude to an outside of the substrate.

The display device may further include a filler filling a space between the sidewall and the first light emitting element.

The substrate may include a sidewall in the first hole, the is sidewall being perpendicular to a lower surface of the substrate, the substrate may further include a protrusion protruding from the sidewall and integral with the substrate, the protrusion may contact a portion of the first surface, and the protrusion may expose another portion of the first surface.

A thickness of the substrate may be less than a length of the first light emitting element, and a portion of the first light emitting element may protrude to an outside of the substrate.

A thickness of the substrate may be greater than a length of the first light emitting element, and the first light emitting element may be disposed in the first hole of the substrate.

The display device may further include a common electrode disposed on the lower surface of the substrate and electrically connected to the first surface of the first light emitting element, and a pixel electrode disposed on the upper surface of the substrate and electrically connected to the second surface of the first light emitting element.

The substrate may further include a first circuit area disposed adjacent to the first emission area. The display device may further include a transistor disposed on the upper surface of the substrate in the first circuit area, and the transistor may be electrically connected to the pixel electrode.

The display device may further include a second light emitting element emitting light of a second color different from the first color. The substrate may further include a second emission area disposed adjacent to the first emission area, and a second hole passing through the substrate in the second emission area. A diameter of the second hole may be less than a diameter of the first hole, and at least a portion of the second light emitting element may be disposed in the second hole.

A diameter of the second light emitting element may be less than a diameter of the first light emitting element.

The second light emitting element may include a first surface and a second surface facing each other. The display device may further include a common electrode disposed on the lower surface of the substrate and electrically connected to the first surface of the first light emitting element and the first surface of the second light emitting element, a first pixel electrode disposed on the upper surface of the substrate and electrically connected to the second surface of the first light emitting element, and a second pixel electrode disposed on the upper surface of the substrate and electrically connected to the second surface of the second light emitting element.

The display device may further include a plurality of channel walls disposed on a lower surface of the substrate. the plurality of channel walls may not overlap the first hole in a plan view.

According to an embodiment of the disclosure for achieving the above-described object, a method of manufacturing a display device may include preparing a substrate including a first hole passing through the substrate, providing a first mixed liquid including a first light emitting element emitting light of a first color on the substrate, and vertically aligning the first light emitting element in the first hole by setting a first pressure of an upper portion of the substrate to be higher than a second pressure of a lower portion of the substrate.

The first light emitting element may include a first surface and a second surface opposite to each other, and an aspect ratio of the first light emitting element may be greater than 1.

A diameter of the first surface may be less than a diameter of the second surface, and in the vertically aligning of the first light emitting elements, the first surface may be disposed adjacent to a lower surface of the substrate, and the second surface may be disposed adjacent to an upper side of the substrate.

The substrate may further include a second hole passing through the substrate. The method may further include providing a second is mixed liquid including a second light emitting element emitting light of a second color different from the first color on the substrate, and vertically aligning the second light emitting element in the second hole by setting the first pressure to be higher than the second pressure. A diameter of the second hole may be less than a diameter of the first hole, and a diameter of the second light emitting element may be less than a diameter of the first light emitting element.

The substrate may further include a third hole passing through the substrate. The method may further include providing a third mixed liquid including a third light emitting element emitting light of a third color different from the first color and the second color on the substrate, and vertically aligning the third light emitting element in the third hole by setting the first pressure to be higher than the second pressure. A diameter of the third hole may be less than the diameter of the first hole and the diameter of the second hole, and a diameter of the third light emitting element may be less than the diameter of the first light emitting element and the diameter of the second light emitting element.

The method may further include disposing a common electrode electrically connected to the first light emitting element and the second light emitting element on a lower surface of the substrate, disposing a first pixel electrode electrically connected to the first light emitting element on an upper surface of the substrate, and disposing a second pixel electrode electrically connected to the second light emitting element on the upper surface of the substrate.

The details of other embodiments are included in the detailed description and drawings.

In accordance with embodiments of the disclosure, a light emitting element may be aligned and fixed in a vertical direction according to a pressure difference to a substrate including a through hole. Accordingly, an area in which a light emitting element is disposed may be widely secured, and a high-resolution display device may be implemented.

Since the light emitting element is disposed in the vertical direction, because light emitted from the light emitting element is directly emitted upward, light output efficiency of the display device may be improved, and a reflective partition wall for reflecting light of a horizontal direction in a vertical direction may be omitted.

Since the light emitting element is physically fixed in a hole of the substrate according to the pressure difference between an upper portion and a lower portion of the substrate, a separate fixing layer for fixing the light emitting element may be omitted, and alignment accuracy of the light emitting element in the display device may be improved.

A light emitting element of a desired color may be disposed at a desired position by adjusting a size of the light emitting element and a size of the hole of the substrate.

An effect according to embodiments is not limited by the contents above, and more various effects are included in the specification.

### BRIEF DESCRIPTION OF THE DRAWINGS

FIG. 1 is a perspective view illustrating a light emitting element according to an embodiment.

FIG. 2 is a schematic cross-sectional view illustrating a light emitting element according to an embodiment.

FIG. 3 is a perspective view illustrating a light emitting element according to an embodiment.

FIG. 4 is a schematic cross-sectional view illustrating a light emitting element according to an embodiment.

FIG. 5 is a perspective view illustrating a light emitting element according to an embodiment.

FIG. 6 is a perspective view illustrating a light emitting element according to an embodiment.

FIG. 7 is a perspective view illustrating a light emitting element according to an embodiment.

FIG. 8 is a plan view schematically illustrating a display device according to an embodiment.

FIGS. 9A to 9C are schematic diagrams of an equivalent circuit of a pixel according to an embodiment, respectively.

FIG. 10 is a schematic diagram of an equivalent circuit of a pixel according to an embodiment.

FIG. 11 is a schematic exploded perspective view of the display device of FIG. 8.

FIG. 12 is a plan view of the display device of FIG. 11.

FIG. 13 is a schematic cross-sectional view of the display device taken along a line A-A′ of FIG. 12.

FIG. 14 is a schematic cross-sectional view of the display device taken along a line B-B′ of FIG. 12.

FIG. 15 is a schematic cross-sectional view of a display device taken along line B-B′ of FIG. 12 according to an embodiment.

FIG. 16 is a schematic cross-sectional view of a display device taken along line B-B′ of FIG. 12 according to an embodiment.

FIG. 17 is a schematic cross-sectional view of a display device taken along line B-B′ of FIG. 12 according to an embodiment.

FIG. 18 is a schematic cross-sectional view of a display device taken along line B-B′ of FIG. 12 according to an embodiment.

FIG. 19 is a schematic cross-sectional view of a display device taken along line B-B′ of FIG. 12 according to an embodiment.

FIG. 20 is a schematic cross-sectional view of a display device taken along line B-B′ of FIG. 12 according to an embodiment.

FIGS. 21 to 27 are perspective views and schematic cross-sectional views sequentially illustrating a method of manufacturing a display device according to an embodiment of the disclosure.

### DETAILED DESCRIPTION OF THE EMBODIMENTS

The advantages and features of the disclosure and a method of achieving them will become apparent with reference to the embodiments described in detail below together with the accompanying drawings. However, the disclosure is not limited to the embodiments disclosed below, and may be implemented in various different forms. The embodiments are provided so that the disclosure will be more thorough and complete and those skilled in the art to which the disclosure pertains can fully understand the scope of the disclosure. The disclosure may be defined by the scope of the claims.

When an element, such as a layer, is referred to as being “on”, “connected to”, or “coupled to” another element or layer, it may be directly on, connected to, or coupled to the other element or layer or intervening elements or layers may be present. When, however, an element or layer is referred to as being “directly on”, “directly connected to”, or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. A shape, a size, a ratio, an angle, the number, and the like disclosed in the drawings for describing the embodiments are not limited thereto. The same reference numerals denote to the same components throughout the specification. Parts unrelated to is the disclosure in the drawings may be omitted or simply expressed in order to clarify the description of the disclosure.

Although a first, a second, and the like are used to describe various components, these components are not limited by these terms. These terms are used only to distinguish one component from another component. Therefore, a first component mentioned below may be a second component within the technical scope of the disclosure. Singular expressions include plural expressions unless the context clearly indicates otherwise.

Each of features of various embodiments of the disclosure may be coupled or combined with each other in part or in whole, and technically various interlocking and driving are possible. Each embodiment may be implemented independently of each other and association thereof may be implemented together.

In the specification and the claims, the phrase “at least one of” is intended to include the meaning of “at least one selected from the group of” for the purpose of its meaning and interpretation. For example, “at least one of A and B” may be understood to mean “A, B, or A and B.”

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” The terms “about” or “approximately” as used herein is inclusive of the stated value and means within an acceptable range of deviation for the particular value as determined by one of ordinary skill in the art, considering the measurement in question and the error associated is with measurement of the particular quantity (for example, the limitations of the measurement system). For example, “about” may mean within one or more standard deviations, or within ±30%, 20%, 10%, 5% of the stated value.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described in detail with reference to the accompanying drawings.

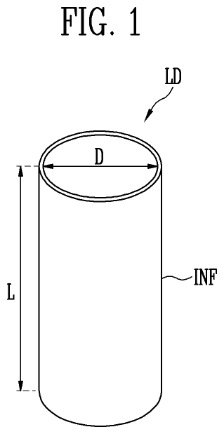

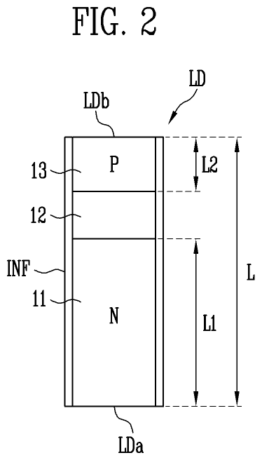

FIG. 1 is a perspective view illustrating a light emitting element according to an embodiment and FIG. 2 is a schematic cross-sectional view illustrating a light emitting element according to an embodiment. Although a rod-shaped light emitting element LD of a cylindrical shape is shown in FIGS. 1 and 2, a type and/or a shape of the light emitting element LD are/is not limited thereto.

Referring to FIGS. 1 and 2, the light emitting element LD may include a first semiconductor layer 11, a second semiconductor layer 13, and an active layer 12 interposed between the first semiconductor layer 11 and the second semiconductor layer 13. For example, the light emitting element LD may be formed as a stack in which the first semiconductor layer 11, the active layer 12, and the second semiconductor layer 13 are sequentially stacked in a direction.

According to an embodiment, the light emitting element LD may be a rod-shaped light emitting diode manufactured in a rod shape. The rod shape may include a rod-like shape or a bar-like shape that is longer in a longitudinal direction than a width direction, such as a cylinder or polygonal column, but a shape of a cross-section thereof is not particularly limited. For example, a length L of the light emitting element LD may be greater than a diameter D (or a width of the cross-section) of the light emitting element LD. For example, an aspect ratio of the light emitting element LD may be greater than 1.

The light emitting element LD may include a first surface LDa and a second surface LDb opposite to each other in a direction. The first surface LDa and the second surface LDb may be surfaces exposed to an outside. For example, the first semiconductor layer 11 may be disposed on the first surface LDa of the light emitting element LD, and the second semiconductor layer 13 may be disposed on the second surface LDb of the light emitting element LD, but the first semiconductor layer 11 and the second semiconductor layer 12 may be disposed on opposite surfaces.

According to an embodiment, the light emitting element LD may have a size as small as nano-scale to micro-scale, for example, the diameter D and/or the length L may be in a range of about 100 nm to about 10 μm. However, a size of the light emitting element LD is not limited thereto. For example, the size of the light emitting element LD may be variously changed according to design condition of various devices using the light emitting element LD as a light source, for example, a display device or the like.

The first semiconductor layer 11 may include at least one n-type semiconductor material. For example, the first semiconductor layer 11 may include an n-type semiconductor material including a semiconductor material such as InAlGaN, GaN, AlGaN, InGaN, AlN, or InN, doped with a first conductive dopant such as Si, Ge, Se, or Sn. However, a material is configuring the first semiconductor layer 11 is not limited thereto, and various other materials may configure the first semiconductor layer 11.

The active layer 12 may be formed on the first semiconductor layer 11 and may include a single or multiple quantum well structure. In case that the active layer 12 includes a material of the multiple quantum well structure, the active layer 12 may include a structure in which a quantum layer and a well layer are stacked alternately with each other.

In case that an electric field of a predetermined voltage or more is applied to both ends (or the first surface LDa and the second surface LDb) of the light emitting element LD, the light emitting element LD may emit light as an electron-hole pair is coupled in the active layer 12. By controlling light emission of the light emitting element LD by using such a principle, the light emitting element LD may be used as a light source of various light emitting devices including a pixel of the display device.

The active layer 12 may emit light having a wavelength of about 400 nm to about 900 nm. For example, in case that the active layer 12 emits light of a blue or green wavelength band, the active layer 12 may include an inorganic material including nitrogen such as AlGaN or InAlGaN. For example, in cast that the active layer 12 is the structure in which the quantum layer and the well layer are alternately stacked each other in the multiple quantum well structure, the quantum layer may include an inorganic material such as AlGaN or InAlGaN, and the well layer may include an inorganic material such as GaN or AlInN. In an embodiment, the active layer 12 may include InAlGaN as the quantum layer and AlInN as the well layer.

However, a material and a structure of the light emitting element LD are not limited thereto, and the active layer 12 may include a structure in which a semiconductor material of which energy band gap is large and semiconductor materials of which energy band gap is small are alternately stacked with each other. The active layer 12 may include group III to V semiconductor materials depending on a wavelength band of emitted light. The light emitted by the active layer 12 is not limited to the light of the blue or green wavelength band, and may be light of a red wavelength band according to the included material.

The light emitted from the active layer 12 may be emitted to the first surface LDa and the second surface LDb of the light emitting element LD in the longitudinal direction of the light emitting element LD. Some light emitted from the active layer 12 may be emitted to a side surface (or an outer circumferential surface) of the active layer 12. For example, a directionality of the light emitted from the active layer 12 is not limited to one direction.

The second semiconductor layer 13 may be disposed on the active layer 12 and may include a semiconductor material different from that of the first semiconductor layer 11. For example, the second semiconductor layer 13 may include at least one p-type semiconductor material. For example, the second semiconductor layer 13 may include a p-type semiconductor material including at least one semiconductor material such as InAlGaN, GaN, AlGaN, InGaN, AlN, or InN, doped with a second conductive dopant such as Mg, Zn, Ca, or Ba. However, a material configuring the second semiconductor layer 13 is not limited thereto, and various other materials may configure the second semiconductor layer 13.

In the drawing, the first semiconductor layer 11 and the second semiconductor layer 13 are configured as one layer, but the disclosure is not limited thereto. For example, the first semiconductor layer 11 and the second semiconductor layer 13 may include a greater number of layers depending on the material of the active layer 12. For example, the first semiconductor layer 11 and the second semiconductor layer 13 may further include a clad layer or a tensile strain barrier reducing (TSBR) layer.

According to an embodiment, a first length L1 of the first semiconductor layer 11 may be greater than a second length L2 of the second semiconductor layer 13.

According to an embodiment, a side surface of the light emitting element LD (for example, an outer circumferential surface of the light emitting element LD) may be parallel to the longitudinal direction of the light emitting element LD. For example, the side surface of the light emitting element LD may extend in a direction perpendicular to the first surface LDa and the second surface LDb.

According to an embodiment, the light emitting element LD may further include an insulating film INF provided on a surface. The insulating film INF may be formed on a surface of the light emitting element LD to surround the outer circumferential surface of the active layer 12, and may further surround the first semiconductor layer 11 and the second semiconductor layer 13.

According to an embodiment, the insulating film INF may expose the first surface LDa and the second surface LDb of the light emitting elements LD. For example, the insulating film INF may not cover and expose an outer surface of each of the first semiconductor layer 11 and the second semiconductor layer 13 positioned at both ends of the light emitting element LD on the longitudinal direction, for example, two planes (for example, the first surface LDa and the second surface LDb) of a cylinder.

According to an embodiment, the insulating film INF may include a transparent insulating material. For example, the insulating film INF may include at least one or more inorganic insulating materials such as SiO₂, Si₃N₄, Al₂O₃, or TiO₂, but a material of the insulating film INF is not particularly limited, and may include various insulating materials.

In an embodiment, the insulating film INF may include a single layer structure. In case that the insulating film INF includes a single layer structure, the insulating film INF may be formed of one of the above-described inorganic insulating materials. In another embodiment, the insulating film INF may include a multiple layer structure. In case that the is insulating film INF includes a multiple layer structure, each of layers of the insulating film INF may be formed of one of the above-described inorganic insulating materials.

The insulating film INF may prevent an electrical short circuit that may occur in case that the active layer 12 contacts a conductive material other than the first semiconductor layer 11 and the second semiconductor layer 13. By forming the insulating film INF, a surface defect of the light emitting element LD may be minimized to improve life and efficiency.

In an embodiment, the light emitting element LD may further include an additional component disposed on and/or under each layer in addition to the first semiconductor layer 11, the active layer 12, the second semiconductor layer 13, and/or the insulating film INF. For example, the light emitting element LD may further include one or more phosphor layers, active layers, semiconductor material layers, and/or electrode layers disposed on a side of the first semiconductor layer 11, the active layer 12, and/or the second semiconductor layer 13.

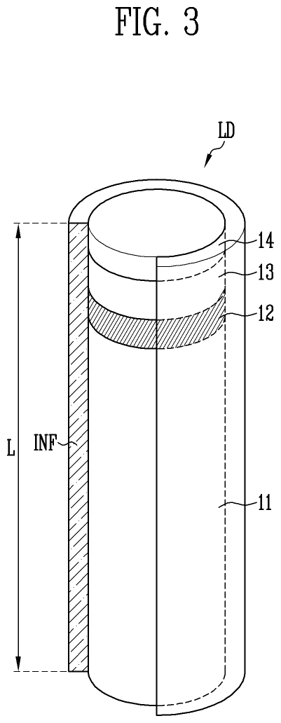

FIG. 3 is a perspective view illustrating a light emitting element according to an embodiment. In FIG. 3, a portion of the insulating film INF is omitted for convenience of description.

Referring to FIG. 3 in conjunction with FIGS. 1 and 2, the light emitting element LD may further include an electrode layer 14 disposed on the second semiconductor layer 13.

The electrode layer 14 may be an ohmic contact electrode electrically connected to the second semiconductor layer 13, but the disclosure is not limited thereto. According to an embodiment, the electrode layer 14 may be a Schottky contact electrode. The electrode layer 14 may include a metal or a metal oxide. For example, the electrode layer 14 may include Cr, Ti, Al, Au, Ni, indium tin oxide (ITO), indium zinc oxide (IZO), indium tin-zinc oxide (ITZO), or the like.

According to an embodiment, the electrode layer 14 may be substantially transparent or translucent. Accordingly, the light generated in the active layer 12 of the light emitting element LD may pass through the electrode layer 14 and may be emitted to the outside of the light emitting element LD.

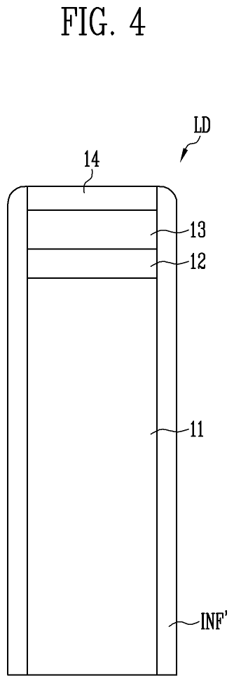

FIG. 4 is a schematic cross-sectional view illustrating a light emitting element according to an embodiment.

Referring to FIG. 4 in conjunction with FIG. 3, the insulating film INF′ may have at least a partially curved shape in a corner area adjacent to the electrode layer 14. According to an embodiment, the curved shape may be formed due to an etching process when the light emitting element LD is manufactured.

Even though the electrode layer 14 is not included in the light emitting element LD in FIGS. 1 and 2, the insulating film INF in FIGS. 1 and 2 may have at least a partially curved shape in the corner area.

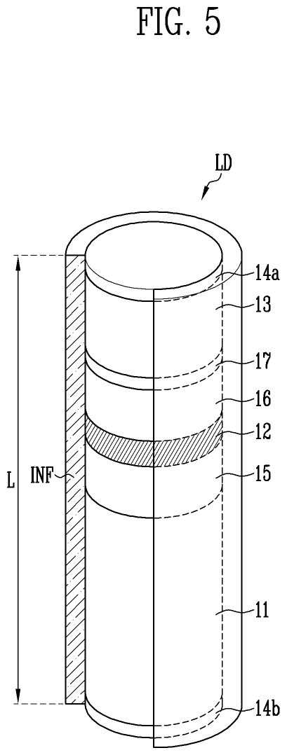

FIG. 5 is a perspective view illustrating a light emitting element according to an embodiment. In FIG. 5, a portion of the insulating film INF is omitted for convenience of description.

Referring to FIG. 5 in conjunction with FIGS. 1 and 2, the light emitting element LD may further include a third semiconductor layer 15 disposed between the first semiconductor layer 11 and the active layer 12, and a fourth semiconductor layer 16 and a fifth semiconductor layer 17 disposed between the active layer 12 and the second semiconductor layers 13. The light emitting element LD may further include a first electrode layer 14a formed on an upper surface of the second semiconductor layer 13 and a second electrode layer 14b formed on a lower surface of the first semiconductor layer 11.

The light emitting element LD of FIG. 5 is different from the embodiment of FIG. 1, in that the semiconductor layers 15, 16, and 17 and the electrode layers 14a and 14b are further disposed, and the active layer 12 includes another element. A disposition and a structure of the insulating film INF are substantially the same as those of FIG. 1.

As described above, in the light emitting element LD of FIG. 1, the active layer 12 may emit the blue or green light by including nitrogen (N). The light emitting element LD of FIG. 5 may be a semiconductor in which each of the active layer 12 and the other semiconductor layers 11, 13, 15, 16, and 17 includes phosphorus (P). For example, the light emitting element LD according to the embodiment of FIG. 5 may emit red light having a center wavelength range of about 620 nm to about 750 nm. However, it should be understood that the center wavelength band of the red light is not limited to the above-described range and the center wavelength band of red light may include all wavelength ranges that may be recognized as red in the technical field.

For example, in the light emitting element LD according to the embodiment of FIG. 5, the first semiconductor layer 11 may include an n-type semiconductor material. For example, the first semiconductor layer 11 may include an n-type semiconductor material including at least one semiconductor material such as InAlGaP, GaP, AlGaP, InGaP, AlP, or InP, doped with a first conductive dopant such as Si, Ge, Se, or Sn. In an embodiment, the first semiconductor layer 11 may be InAlGaP doped with an n-type dopant Si.

The second semiconductor layer 13 may include a p-type semiconductor material. For example, the second semiconductor layer 13 may include a p-type semiconductor material including at least one semiconductor material such as InAlGaP, GaP, AlGaP, InGaP, AlP, or InP, doped with a second conductive dopant such as Mg, Zn, Ca, or Ba. In an embodiment, the second semiconductor layer 13 may be GaP doped with a p-type dopant Mg.

The active layer 12 may be disposed between the first semiconductor layer 11 and the second semiconductor layer 13. Identically to the active layer 12 of FIG. 2, the active layer 12 of FIG. 5 may also emit light of a specific wavelength band by including a single or multiple quantum well structure material. For example, the active layer 12 may include a material of AlGaP, InAlGaP, or the like. For example, in case that the active layer 12 has a structure in which the quantum layer and the well layer are alternately stacked each other in the multiple quantum well structure, the quantum layer may include a material such as AlGaP or InAlGaP, and the well layer may include a material such as GaP or AlInP. In an embodiment, the active layer 12 may emit red light having a center wavelength band of about 620 nm to about 750 nm, by including InAlGaP as the quantum layer and AlInP as the well layer.

The light emitting element LD of FIG. 5 may include a clad layer disposed adjacent to the active layer 12. For example, the third semiconductor layer 15 and the fourth semiconductor layer 16 disposed between the first semiconductor layer 11 and the second semiconductor layer 13 on and under the active layer 12 may be clad layers.

The third semiconductor layer 15 may be disposed between the first semiconductor layer 11 and the active layer 12. The third semiconductor layer 15 may include an n-type semiconductor material similarly to the first semiconductor layer 11. In an embodiment, the third semiconductor layer 15 may include n-AlInP, but the disclosure is not limited thereto.

The fourth semiconductor layer 16 may be disposed between the active layer 12 and the second semiconductor layer 13. The fourth semiconductor layer 16 may include a p-type semiconductor material similarly to the second semiconductor layer 13. In an embodiment, the fourth semiconductor layer 16 may include p-AlInP, but the disclosure is not limited thereto.

The fifth semiconductor layer 17 may be disposed between the fourth semiconductor layer 16 and the second semiconductor layer 13. The is fifth semiconductor layer 17 may include a p-type semiconductor material similarly to the second semiconductor layer 13 and the fourth semiconductor layer 16. According to an embodiment, the fifth semiconductor layer 17 may function of reducing a lattice constant difference between the fourth semiconductor layer 16 and the second semiconductor layer 13. For example, the fifth semiconductor layer 17 may be a tensile strain barrier reducing (TSBR) layer. In an embodiment, the fifth semiconductor layer 17 may include p-GaInP, p-AlInP, p-InAlGaP, and the like, but the disclosure is not limited thereto.

The first electrode layer 14a and the second electrode layer 14b may be disposed on the first semiconductor layer 11 and the second semiconductor layer 13, respectively. The first electrode layer 14a may be disposed on an upper surface of the second semiconductor layer 13, and the second electrode layer 14b may be disposed on a lower surface of the first semiconductor layer 11. According to an embodiment, at least one of the first electrode layer 14a and the second electrode layer 14b may be omitted. Each of the first electrode layer 14a and the second electrode layer 14b may include at least one of the materials that may be used for in the electrode layer 14 of FIG. 3.

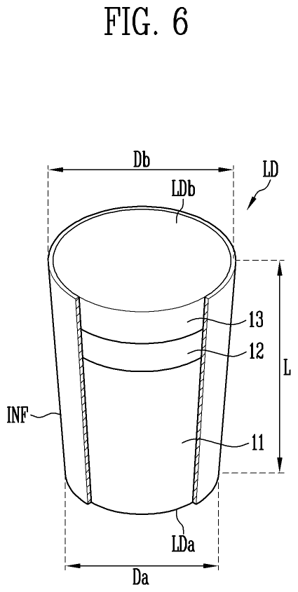

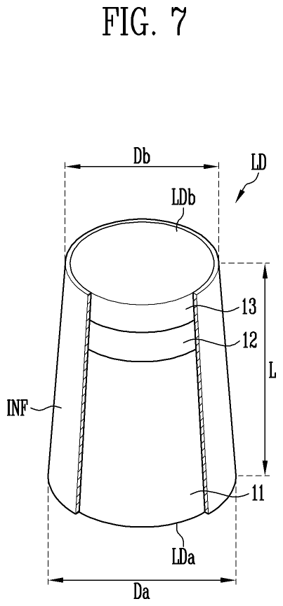

FIG. 6 is a perspective view illustrating a light emitting element according to an embodiment and FIG. 7 is a perspective view illustrating a light emitting element according to an embodiment. In FIGS. 6 and 7, a portion of the insulating film INF is omitted for convenience of description.

Referring to FIGS. 1, 2, 6, and 7, the light emitting element LD of FIG. 6 may be provided in a vertically asymmetric shape in which the area of the first surface LDa of the first semiconductor layer 11 and the area of the second surface LDb of the second semiconductor layer 13 are different from each other, differently from the light emitting element LD of FIGS. 1 and 2. For example, the light emitting element LD may be is provided in a truncated shape such as a truncated cone shape or a polygonal truncated shape. For example, the light emitting element LD may include the first surface LDa and the second surface LDb that are parallel to each other and have different areas, and may have an isosceles trapezoidal shape in cross-section view.

For example, as shown in FIG. 6, a first diameter Da of the first surface LDa of the light emitting element LD may be less than a second diameter Db of the second surface LDb. Accordingly, the side surface (for example, the outer circumferential surface of the light emitting element LD) of the light emitting element LD between the first surface LDa and the second surface LDb may have an angle (for example, an obtuse angle) with respect to the first surface LDa.

In another embodiment, as shown in FIG. 7, the first diameter Da of the first surface LDa of the light emitting element LD may be greater than the second diameter Db of the second surface LDb. Accordingly, the side surface of the light emitting element LD (For example, the outer circumferential surface of the light emitting element LD) may have an angle (for example, an acute angle) with respect to the first surface LDa.

The aspect ratio of the light emitting elements LDs of FIGS. 6 and 7 may be 1 or more. For example, the length L of the light emitting element LD may be greater than the first diameter Da of the first surface LDa and the second diameter Db of the second surface LDb.

In the following embodiments, the light emitting elements LD included in the display device may be at least one of the light emitting elements LD of FIGS. 1 to 7 described above. In an embodiment, the display device may include the rod-shaped light emitting element shown in FIGS. 1 to 5, and in another embodiment, the display device may include the truncated light emitting element shown in FIGS. 6 and 7. This is described later in detail.

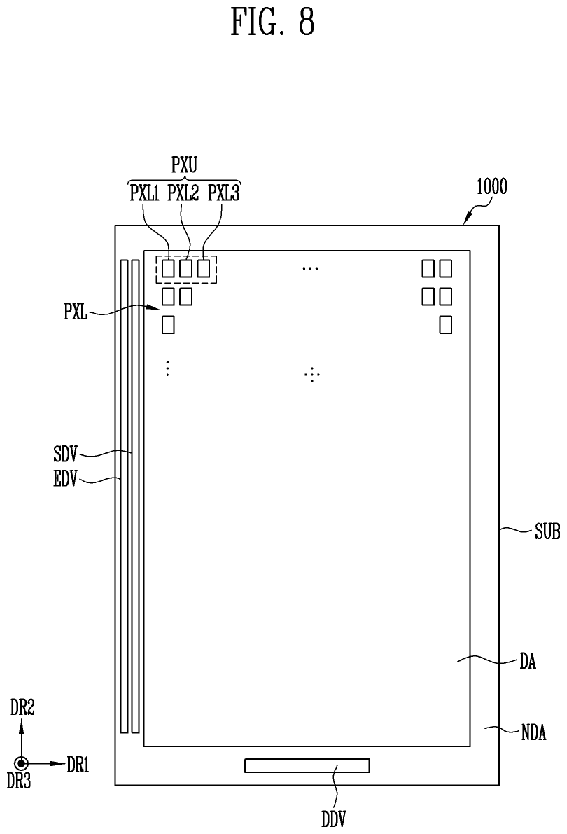

FIG. 8 is a plan view schematically illustrating a display device is according to an embodiment.

Referring to FIG. 8, the display device 1000 may include a substrate SUB and multiple pixels PXL provided on the substrate SUB. The substrate SUB may include a display area DA in which the pixels PXL are disposed to display an image, and a non-display area NDA other than the display area DA.

The substrate SUB may be formed of glass, quartz, ceramic, plastic, or the like. In case that the substrate SUB includes plastic, the substrate SUB may be a flexible substrate, but the disclosure is not limited thereto. For example, the substrate SUB may include an organic material such as polyimide (PI).

The display area DA may be an area in which the pixels PXL are provided. The non-display area NDA may be an area in which drivers SDV, DDV, and EDV for driving the pixels PXL and various lines electrically connecting the pixels PXL and the drivers SDV, DDV, and EDV are provided.

The display area DA may have various shapes. For example, the display area DA may be provided in various shapes, such as a closed polygon including a side formed of a straight line, a circle, an ellipse, and the like including a side formed of a curve, and a semicircle, a semi-ellipse, and the like including a side formed of a straight line and a curve.

In case that the display area DA includes multiple areas, each area may also be provided in the various shapes described above. The areas of the multiple areas may be identical to each other or different from each other. In an embodiment of the disclosure, a case in which the display area DA is provided as one area having a quadrangular shape including a side of a straight line is described as an embodiment.

The non-display area NDA may be provided on at least one side of the display area DA. In an embodiment, the non-display area NDA may surround the display area DA.

The pixels PXL may be provided in the display area DA of the is substrate SUB. Each of the pixels PXL may include at least one light emitting element LD electrically connected to a scan line and a data line to be driven by a corresponding scan signal and data signal.

Each of the pixels PXL may emit light of one color among red, green, and blue, but the disclosure is not limited thereto. For example, each of the pixels PXL may emit light of one color among cyan, magenta, yellow, and white.

For example, the pixels PXL may include a first pixel PXL1 (or a first sub-pixel) emitting light of a first color, a second pixel PXL2 (or a second sub-pixel) emitting light of a second color different from the first color, and a third pixel PXL3 (or a third sub-pixel) emitting light of a third color different from the first color and the second color. The first pixel PXL1, the second pixel PXL2, and the third pixel PXL3 disposed adjacent to each other may configure one pixel unit PXU capable of emitting light of various colors.

According to an embodiment, the first pixel PXL1 may be a red pixel emitting red light, the second pixel PXL2 may be a green pixel emitting green light, and the third pixel PXL3 may be a blue pixel emitting blue light.

The pixels PXL may be provided in plural and may be arranged in a first direction DR1 and a second direction DR2 intersecting the first direction DR1. However, an arrangement of the pixels PXL is not particularly limited and may be arranged in various forms.

The drivers SDV, DDV, and EDV may provide a signal to each of the pixels PXL through each line unit (not shown), and thus may control driving of each of the pixels PXL. In FIG. 8, the line unit is omitted for convenience of description.

The drivers SDV, DDV, and EDV may include a scan driver SDV that provides a scan signal to the pixels PXL through a scan line, a data driver DDV that provides a data signal to the pixels PXL through a data line, an emission control driver EDV that provides an emission control signal to is the pixels PXL through an emission control line, and a timing controller (not shown). The timing controller may control the scan driver SDV, the data driver DDV, and the emission control driver EDV.

According to an embodiment, the emission control driver EDV may be omitted. According to an embodiment, the timing controller may be integrated into the data driver DDV and may be provided as one configuration.

The scan driver SDV may be disposed on a side of the substrate SUB and may be disposed in a direction (for example, the second direction DR2). The scan driver SDV may be mounted on the substrate SUB as a separate part, but the disclosure is not limited thereto. For example, the scan driver SDV may be directly formed on the substrate SUB, or may be positioned outside the substrate SUB and may be electrically connected to each of the pixels PXL through a connection member.

The data driver DDV may be disposed on a side of the substrate SUB, and may be disposed in a direction intersecting the scan driver SDV (for example, the first direction DR1). The data driver DDV may be mounted on the substrate SUB as a separate part, or may be positioned outside the substrate SUB and may be electrically connected to each of the pixels PXL through a connection member.

The emission control driver EDV may be disposed on a side of the substrate SUB, and may be disposed in the same direction as the scan driver SDV (for example, the second direction DR2). As shown in FIG. 8, the emission control driver EDV may be disposed on the same side as the scan driver SDV, but the disclosure is not limited thereto. For example, the emission control driver EDV may be disposed on a side different from the side the scan driver SDV is disposed. The emission control driver EDV may be mounted on the substrate SUB as a separate part, but the disclosure is not limited thereto. For example, the emission control driver EDV may be directly formed on the substrate SUB, or positioned outside the substrate is SUB and may be electrically connected to each of the pixels PXL through a connection member.

In an embodiment, each of the pixels PXL may be configured as an active pixel. However, a type, a structure, and/or a driving method of the pixels PXL applicable to the disclosure are/is not particularly limited.

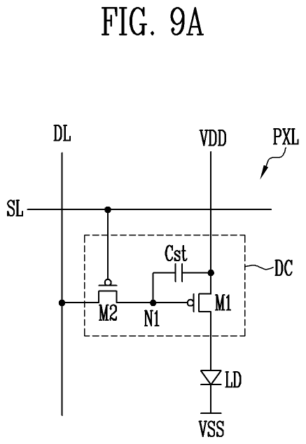

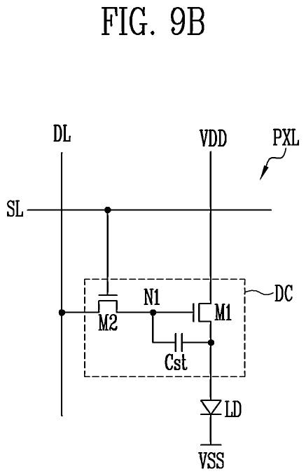

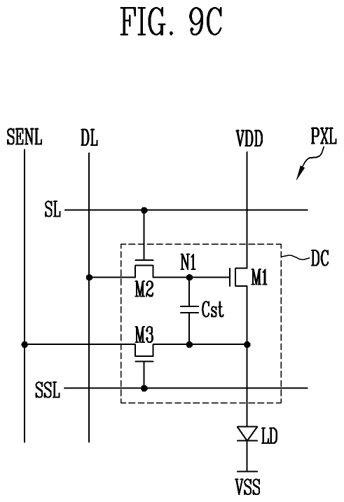

FIGS. 9A to 9C are schematic diagrams of an equivalent circuit of a pixel according to an embodiment, respectively. For example, FIGS. 9A to 9C show an embodiment of the pixel configuring an active light emitting display panel.

Referring to FIGS. 1, 2, and 9A, the pixel PXL may include at least one light emitting element LD and a driving circuit DC electrically connected to the light emitting element LD to drive the light emitting element LD.

A first electrode (for example, an anode) of the light emitting element LD may be electrically connected to first driving power supply VDD through the driving circuit DC, and a second electrode (for example, a cathode) of the light emitting element LD may be electrically connected to second driving power supply VSS. The light emitting element LD may emit light with a luminance corresponding to a driving current amount controlled by the driving circuit DC.

Although only one light emitting element LD is shown in FIG. 9A, FIG. 9A merely illustrates a configuration, and according to an embodiment, one pixel PXL may include multiple light emitting elements LD. The light emitting elements LD included in the pixel PXL may be electrically connected in parallel and/or series with each other.

The first driving power supply VDD and the second driving power supply VSS may have different potentials. For example, the first driving power supply VDD may have a potential equal to or greater than a potential of the second driving power supply VSS by a threshold voltage or more of the light emitting element LD. For example, a voltage applied is through the first driving power supply VDD may be greater than a voltage applied through the second driving power supply VSS.

According to an embodiment of the disclosure, the driving circuit DC may include a first transistor M1, a second transistor M2, and a storage capacitor Cst.

A first electrode of the first transistor M1 (driving transistor) may be electrically connected to the first driving power supply VDD, and a second electrode of the first transistor M1 may be electrically connected to the first electrode (for example, the anode) of the light emitting element LD. A gate electrode of the first transistor M1 may be electrically connected to a first node N1. The first transistor M1 may control a driving current amount supplied to the light emitting elements LD in response to a voltage of the first node N1.

A first electrode of the second transistor M2 (switching transistor) may be electrically connected to a data line DL, and a second electrode of the second transistor M2 may be electrically connected to the first node N1. The first electrode and the second electrode of the second transistor M2 may be different electrodes, for example, in case that the first electrode is a source electrode, the second electrode may be a drain electrode. A gate electrode of the second transistor M2 may be electrically connected to a scan line SL.

The second transistor M2 may be turned on in case that a scan signal of a voltage (for example, a gate on voltage) at which the first transistor M1 may be turned on is supplied from the scan line SL, to electrically connect the data line DL and the first node N1 to each other. A data signal of a corresponding frame may be supplied to the data line DL, and thus the data signal may be transmitted to the first node N1. The data signal transmitted to the first node N1 may be stored in the storage capacitor Cst.

One electrode of the storage capacitor Cst may be electrically is connected to the first driving power supply VDD, and another electrode of the storage capacitor Cst may be electrically connected to the first node N1. The storage capacitor Cst may be charged with a voltage corresponding to the data signal supplied to the first node N1, and may maintain the charged voltage until a data signal of a next frame is supplied.

For convenience of description, FIG. 9A shows the driving circuit DC of a relatively simple structure, which includes the second transistor M2 for transmitting the data signal into each of the pixel PXL, the storage capacitor Cst for storing the data signal, and the first transistor M1 for supplying the driving current corresponding to the data signal to the light emitting element LD.

However, the disclosure is not limited thereto, and a structure of the driving circuit DC may be variously changed and implemented. For example, the driving circuit DC may further include other circuit elements such as a compensation transistor for compensating for a threshold voltage of the first transistor M1, an initialization transistor for initializing the first node N1, and/or an emission control transistor for controlling an emission time of the light emitting element LD.

The FIG. 9A shows that both of the first transistor M1 and the second transistor M2 included in the driving circuit DC are P-type transistors, but the disclosure is not limited thereto. For example, at least one of the first transistor M1 and the second transistor M2 included in the driving circuit DC may be an N-type transistor.

For example, as shown in FIG. 9B, the first transistor M1 and the second transistor M2 of the driving circuit DC may be implemented as N-type transistors. A configuration or an operation of a driving circuit DC shown in FIG. 9B may be similar to that of the driving circuit DC of FIG. 9A except for a connection position of a component (for example, a storage capacitor Cst) due to a different transistor type.

In addition, as another example, referring to FIG. 9C, the pixel is PXL may further include a third transistor M3 (sensing transistor).

A gate electrode of the third transistor M3 may be electrically connected to a sensing signal line SSL. One electrode of the third transistor M3 may be electrically connected to a sensing line SENL, and another electrode of the third transistor M3 may be electrically connected to the first electrode (for example, the anode) of the light emitting element LD. The third transistor M3 may transmit a voltage value of the first electrode of the light emitting element LD to the sensing line SENL according to a sensing signal supplied to the sensing signal line SSL during a sensing period. The voltage value transmitted through the sensing line SENL may be provided to an external circuit (for example, the timing controller), and the external circuit may extract characteristic information (for example, the threshold voltage or the like of the first transistor M1) of the pixel PXL, based on the provided voltage value. The extracted characteristic information may be used to convert image data so that a characteristic deviation of the pixel PXL is compensated.

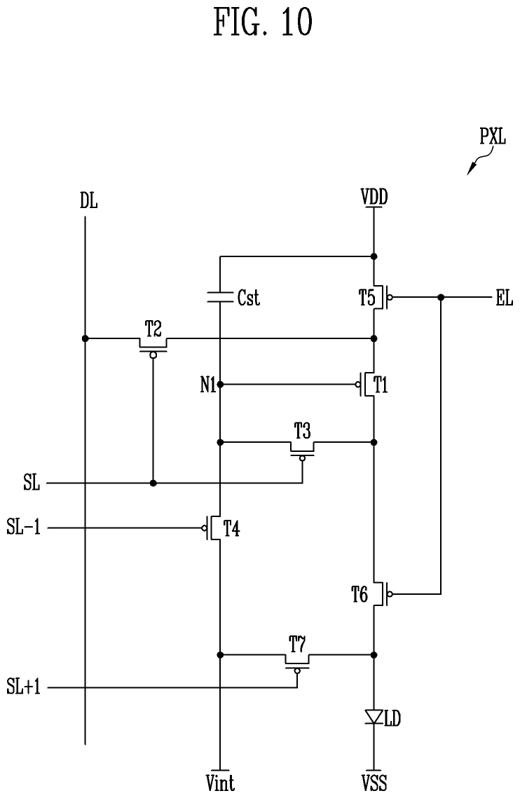

FIG. 10 is a schematic diagram of an equivalent circuit of a pixel according to an embodiment.

Referring to FIG. 10, the pixel PXL according to an embodiment of the disclosure may include a light emitting element LD, first to seventh transistors T1, T2, T3, T4, T5, T6, and T7, and a storage capacitor Cst.

A first electrode (for example, an anode) of the light emitting element LD may be electrically connected to the first transistor T1 via the sixth transistor T6, and a second electrode (for example, a cathode) of the light emitting element LD may be electrically connected to the second driving power supply VSS. The light emitting element LD may emit light with a luminance corresponding to a driving current amount supplied from the first transistor T1.

One electrode of the first transistor T1 (driving transistor) may is be electrically connected to the first driving power supply VDD via the fifth transistor T5, and another electrode of the first transistor T1 may be electrically connected to the first electrode of the light emitting element LD via the sixth transistor T6. The first transistor T1 may control a current amount flowing from the first driving power supply VDD to the second driving power supply VSS via the light emitting element LD, in response to a voltage of the first node N1 that is electrically connected to a gate electrode.

The second transistor T2 (switching transistor) may be electrically connected between the data line DL and an electrode of the first transistor T1. A gate electrode of the second transistor T2 may be electrically connected to the first scan line SL. The second transistor T2 may be turned on in case that a scan signal of a gate on voltage is supplied to the first scan line SL, to electrically connect the data line DL and the electrode of the first transistor T1 to each other.

The third transistor T3 may be electrically connected between another electrode of the first transistor T1 and the first node N1. A gate electrode of the third transistor T3 may be electrically connected to the first scan line SL. The third transistor T3 may be turned on in case that the scan signal of the gate on voltage is supplied to the first scan line SL, to electrically connect the another electrode of the first transistor T1 and the first node N1 to each other.

The fourth transistor T4 may be electrically connected between the first node N1 and initialization power Vint. A gate electrode of the fourth transistor T4 may be electrically connected to a second scan line SL−1. The fourth transistor T4 may be turned on in case that the scan signal of the gate on voltage is supplied to the second scan line SL−1, to supply a voltage of the initialization power Vint to the first node N1. The initialization power Vint may be set to a voltage lower than that of the data signal.

The fifth transistor T5 may be electrically connected between is the first driving power supply VDD and the electrode of the first transistor T1. A gate electrode of the fifth transistor T5 may be electrically connected to an emission control line EL. The fifth transistor T5 may be turned on in case that an emission control signal of a gate on voltage is supplied to the emission control line EL, and may be turned off in other cases.

The sixth transistor T6 may be electrically connected between the another electrode of the first transistor T1 and the first electrode of the light emitting element LD. A gate electrode of the sixth transistor T6 may be electrically connected to the emission control line EL. The sixth transistor T6 may be turned on in case that the emission control signal of the gate on voltage is supplied to the emission control line EL, and may be turned off in other cases.

The seventh transistor T7 may be electrically connected between the initialization power Vint and the first electrode (for example, the anode) of the light emitting element LD. A gate electrode of the seventh transistor T7 may be electrically connected to a third scan line SL+1. The seventh transistor T7 may be turned on in case that the scan signal of the gate on voltage is supplied to the third scan line SL+1, to supply the voltage of the initialization power Vint to the first electrode of the light emitting element LD.

FIG. 10 shows a case where the gate electrode of the seventh transistor T7 is electrically connected to the third scan line SL+1. However, the disclosure is not limited thereto. In another embodiment of the disclosure, the gate electrode of the seventh transistor T7 may be electrically connected to the first scan line SL or the second scan line SL−1. The voltage of the initialization power Vint may be supplied to the anode of the light emitting element LD via the seventh transistor T7 in case that the scan signal of the gate on voltage is supplied to the first scan line SL or the second scan line SL−1.

The storage capacitor Cst may be electrically connected is between the first driving power supply VDD and the first node N1. The storage capacitor Cst may store a voltage corresponding to the data signal and a threshold voltage of the first transistor T1.

In FIG. 10, all of the transistors included in the driving circuit DC, for example, the first to seventh transistors T1, T2, T3, T4, T5, T6, and T7 are P-type transistors, but the disclosure is not limited thereto. For example, at least one of the first to seventh transistors T1, T2, T3, T4, T5, T6, and T7 may be an N-type transistor.

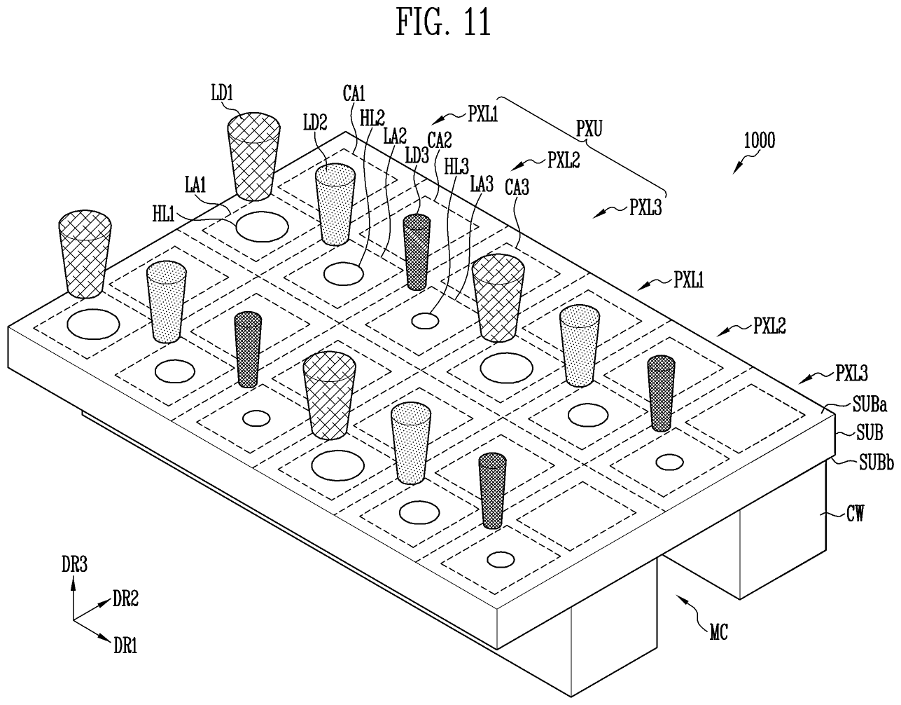

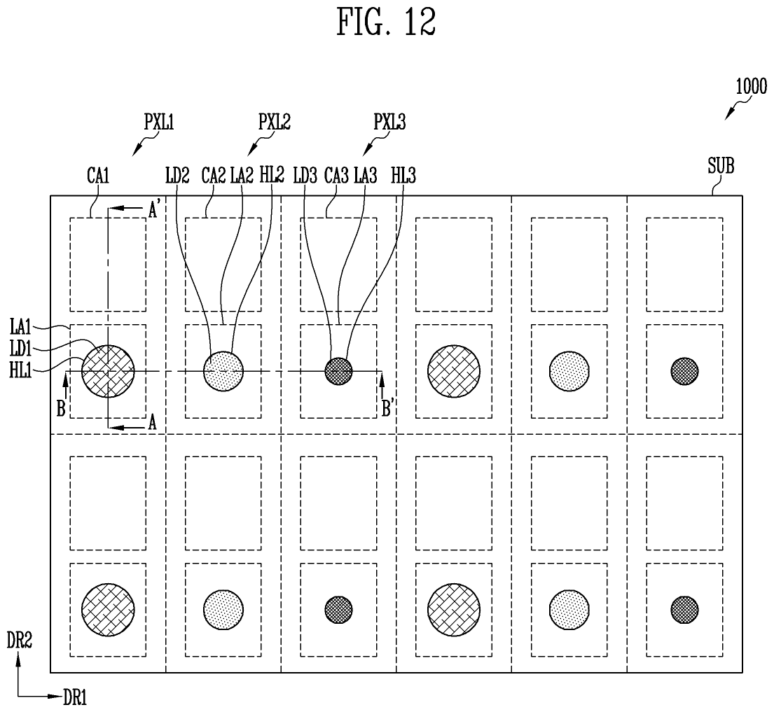

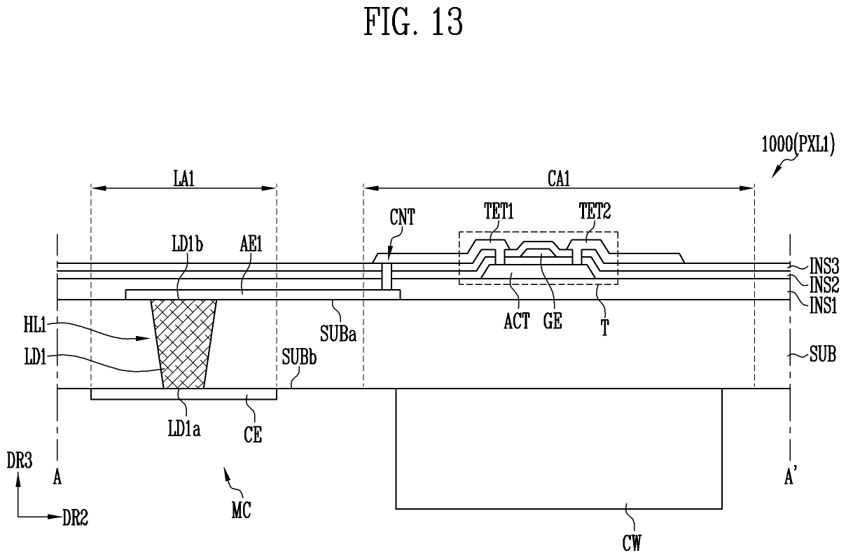

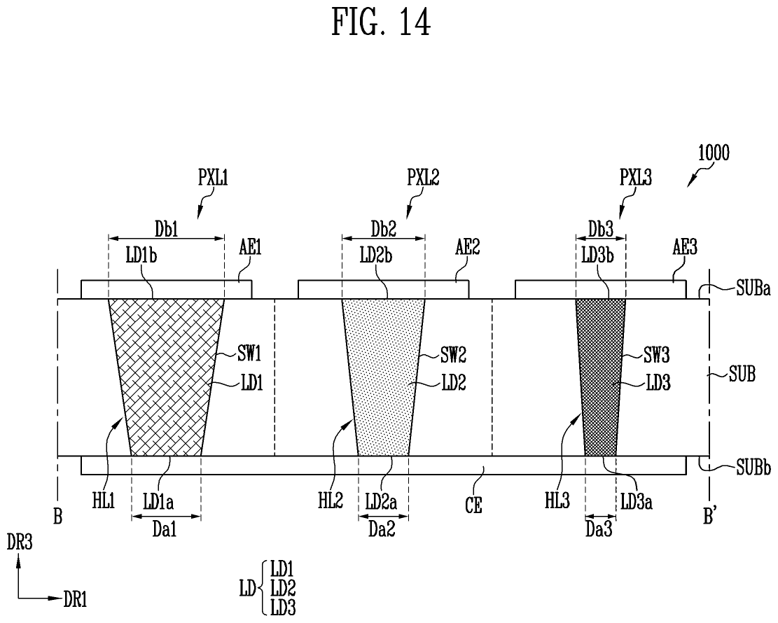

FIG. 11 is a schematic exploded perspective view of the display device of FIG. 8. FIG. 12 is a plan view of the display device of FIG. 11. FIG. 13 is a schematic cross-sectional view of the display device taken along line A-A′ of FIG. 12. FIG. 14 is a schematic cross-sectional view of the display device taken along line B-B′ of FIG. 12. FIGS. 11 to 14 may be enlarged and simplified views of a portion of the display device 1000 of FIG. 8 for convenience of description. Hereinafter, a description of the content overlapping the content described with reference to FIG. 8 is omitted.

Referring to FIGS. 11 to 14, the display device 1000 may include the substrate SUB, and the first pixel PXL1, the second pixel PXL2, and the third pixel PXL3 provided on the substrate SUB. According to an embodiment, the display device 1000 may further include a channel wall CW.

The substrate SUB may include an upper surface SUBa and a lower surface SUBb. The upper surface SUBa and the lower surface SUBb of the substrate SUB may opposite to each other and may be substantially parallel to each other. As an embodiment, the upper surface SUBa and the lower surface SUBb of the substrate SUB may have the same rectangular shape in a plan view, and the substrate SUB may have a rectangular parallelepiped shape as a whole. Hereinafter, “disposed on the upper surface SUBa of the substrate SUB” may mean disposed in a third direction DR3 with respect to the upper surface SUBa of the substrate SUB, and “disposed on the lower surface SUBb of the substrate SUB” may mean is disposed in a direction opposite to the third direction DR3 with respect to the lower surface SUBb of the substrate SUB.

A first hole HL1, a second hole HL2, and a third hole HL3 passing through the substrate SUB may be formed in the substrate SUB. A first light emitting element LD1, a second light emitting element LD2, and a third light emitting element LD3 to be described later may be disposed in the first hole HL1, the second hole HL2, and the third hole HL3, respectively.

The first pixel PXL1, the second pixel PXL2, and the third pixel PXL3 may include the first light emitting element LD1, the second light emitting element LD2, and the third light emitting element LD3, and may emit light of different colors, respectively. As described above, the first pixel PXL1, the second pixel PXL2, and the third pixel PXL3 may configure one pixel unit PXU capable of expressing various colors. In the embodiment, the first light emitting element LD1, the second light emitting element LD2, and the third light emitting element LD3 may be the light emitting element LD of FIG. 6, but the disclosure is not limited thereto.

The first pixel PXL1, the second pixel PXL2, and the third pixel PXL3 may be sequentially arranged on the substrate SUB. For example, in case that the display device 1000 has a pixel arrangement of a stripe manner, the first pixel PXL1, the second pixel PXL2, and the third pixel PXL3 may be sequentially arranged in the first direction DR1, and the pixels may be arranged in the second direction DR2. An arrangement of the first pixel PXL1, the second pixel PXL2, and the third pixel PXL3 is not limited thereto, and the pixels may be arranged in various methods such as a PenTile® method.

Since the first pixel PXL1, the second pixel PXL2, and the third pixel PXL3 may have substantially identical or similar structures, the first pixel PXL1 is described, and a point different from that of the first pixel PXL1 is described regarding the second pixel PXL2 and the third pixel PXL3.

The first pixel PXL1 may include a first emission area LA1 and is a first circuit area CA1 defined on the substrate SUB. The first emission area LA1 may be an area in which the first light emitting element LD1 is disposed, and the first circuit area CA1 may be an area in which circuit elements and lines for providing a driving signal to the first light emitting element LD1 are disposed. A shape and the area of the first emission area LA1 and the first circuit area CA1 may be variously changed as necessary.

In the first emission area LA1, the substrate SUB may include the first hole HL1 in which the first light emitting element LD1 is disposed. As described above, the first hole HL1 may completely pass through the substrate SUB. Multiple first holes HL1 may be formed in the first emission area LA1. According to an embodiment, the first hole HL1 may be formed in substantially the same shape as the first light emitting element LD1, but the disclosure is not limited thereto.

The first light emitting element LD1 may be disposed in the first hole HL1, and at least a portion of the first light emitting element LD1 may be inserted into the substrate SUB through the first hole HL1. For example, the first light emitting element LD1 may be inserted and fixed into the first hole HL1 according to a pressure difference between an upper portion and a lower portion of the substrate SUB.

The second pixel PXL2 may include a second emission area LA2 and a second circuit area CA2. In the second emission area LA2, the substrate SUB may include the second hole HL2 in which the second light emitting element LD2 is disposed. According to an embodiment, a diameter of the second hole HL2 may be less than a diameter of the first hole HL1. The second hole HL2 may be formed in substantially the same shape as the second light emitting element LD2.

The second light emitting element LD2 may be disposed in the second hole HL2. According to an embodiment, a size (or a diameter) of the second light emitting element LD2 may be less than a size (or a diameter) of the first light emitting element LD1, and the second light emitting element LD2 may be inserted into the substrate SUB after the first light emitting element LD1 is disposed.

The third pixel PXL3 may include a third emission area LA3 and a third circuit area CA3. In the third emission area LA3, the substrate SUB may include the third hole HL3 in which the third light emitting element LD3 is disposed. According to an embodiment, a diameter of the third hole HL3 may be less than the diameter of the first hole HL1 and the second hole HL2. The third hole HL3 may be formed in substantially the same shape as the third light emitting element LD3.

The third light emitting element LD3 may be disposed in the third hole HL3. According to an embodiment, a size (or a diameter) of the third light emitting element LD3 may be less than the size (or the diameter) of the first light emitting element LD1 and the size (or the diameter) of the second light emitting element LD2, and the third light emitting element LD3 may be inserted into the substrate SUB after the first light emitting element LD1 and the second light emitting element LD2 are disposed.

FIGS. 11 to 14 illustrate a structure in which one light emitting element LD1, LD2, and LD3 is disposed in each of the emission areas LA1, LA2, and LA3, but the disclosure is not limited thereto. For example, at least two light emitting elements LD1, LD2, and LD3 may be respectively disposed in each of the emission areas LA1, LA2, and LA3. The number of light emitting elements LD1, LD2, and LD3 disposed in each of the emission areas LA1, LA2, and LA3 may be different from each other. In an embodiment, the number of the third light emitting elements LD3 disposed in the third emission area LA3 may be greater than the number of the first light emitting elements LD1 disposed in the first emission area LA1, but the disclosure is not limited thereto.

As shown in FIG. 13, in the first emission area LA1, a first pixel electrode AE1 may be disposed on the upper surface SUBa of the substrate SUB, and a common electrode CE may be disposed on the lower is surface SUBb of the substrate SUB. The first pixel electrode AE1 may be disposed on the first light emitting element LD1 and may be electrically connected to a second surface LD1b of the first light emitting element LD1. A portion of the common electrode CE may be disposed on the first light emitting element LD1 and may be electrically connected to a first surface LD1a of the first light emitting element LD1. According to an embodiment, the first pixel electrode AE1 may electrically contact the second surface LD1b of the first light emitting element LD1, and the common electrode CE may electrically contact the first surface LD1a of the first light emitting element LD1. One of the first pixel electrode AE1 and the common electrode CE may be an anode, and another may be a cathode.

The first pixel electrode AE1 and the common electrode CE may provide a driving signal to the first light emitting element LD1 in response to the scan signal and the data signal, and the first light emitting element LD1 may emit light of a luminance corresponding to the provided driving signal.

Referring to FIG. 13 in conjunction with FIG. 9A, each of the first pixel electrode AE1 and the common electrode CE may be electrically connected to any one of the driving circuit DC and the second driving power supply VSS through a separate connection line or connection member. For example, the first pixel electrode AE1 may be electrically connected to the driving circuit DC, and the common electrode CE may be electrically connected to the second driving power supply VSS. Accordingly, the first pixel electrode AE1 and the common electrode CE may provide the driving signal to the light emitting element LD1.

The first pixel electrode AE1 and the common electrode CE may be formed of a conductive material. In an embodiment, each of the first pixel electrode AE1 and the common electrode CE may include a metal such as Al, Mg, Ag, Pt, Pd, Au, Ni, Nd, Ir, Cr, Ti, or an alloy thereof. In another embodiment, each of the first pixel electrode AE1 and the common is electrode CE may include a transparent conductive material such as indium tin oxide (ITO), indium zinc oxide (IZO), zinc oxide (ZnO), or indium tin zinc oxide (ITZO). In an embodiment, the first pixel electrode AE1 may include a transparent conductive material, and the common electrode CE may include a conductive material having a constant reflectance.

Light emitted from the first light emitting element LD1 may be emitted in the third direction DR3 and the direction opposite to the third direction DR3. In case that the first pixel electrode AE1 includes a transparent conductive material, the light emitted from the first light emitting element LD1 in the third direction DR3 may pass through the first pixel electrode AE1 and proceed. In case that the common electrode CE includes a conductive material having a constant reflectance, the light emitted from the first light emitting element LD1 in the direction opposite to the third direction DR3 may be reflected by the common electrode CE and may proceed in the third direction DR3, and light output efficiency of the display device 1000 may be improved.

Multiple circuit elements configuring the driving circuit (for example, DC of FIG. 9A) of the first pixel PXL1 may be disposed in the first circuit area CA1. For example, at least one transistor T may be disposed in the first circuit area CA1. The transistor T may be the first transistor M1 of FIG. 9A, but the disclosure is not limited thereto.

A first insulating layer INS1 may be disposed on the upper surface SUBa of the substrate SUB. For example, the first insulating layer INS1 may be a buffer layer. The first insulating layer INS1 may be formed entirely on the substrate SUB and may cover the first pixel electrode AE1. The first insulating layer INS1 may provide a space where the transistor T to be disposed in the first circuit area CA1. The first insulating layer INS1 may prevent an impurity from diffusing into circuit elements disposed on the substrate SUB. The first insulating layer INS1 may be an inorganic insulating layer including an inorganic material, but the disclosure is not is limited thereto. The first insulating layer INS1 may be provided as a single layer, or may include a multiple layer structure according to an embodiment. In case that the first insulating layer INS1 includes the multiple layer structure, the first insulating layer INS1 may include an organic insulating layer and an inorganic insulating layer alternately stacked each other.

In the first circuit area CA1, a transistor T may be disposed on the first insulating layer INS1. The transistor T may include an active layer ACT, a gate electrode GE, a first transistor electrode TET1, and a second transistor electrode TET2.

The active layer ACT may be disposed on the first insulating layer INS1. The active layer ACT may include a first area to which the first transistor electrode TET1 is electrically connected, a second area to which the second transistor electrode TET2 is electrically connected, and a channel area positioned between the first and second areas. One of the first and second areas may be a source area, and another may be a drain area.

The active layer ACT may be a semiconductor pattern formed of polysilicon, amorphous silicon, oxide semiconductor, or the like. The channel area of the active layer ACT may include an intrinsic semiconductor as a semiconductor pattern that is not doped with an impurity, and each of the first and second areas of the active layer ACT may be a semiconductor pattern doped with an impurity.

A second insulating layer INS2 may be disposed on the active layer ACT. For example, the second insulating layer INS2 may be a gate insulating layer. The second insulating layer INS2 may completely cover the active layer ACT. For example, the active layer ACT may be disposed between the first insulating layer INS1 and the second insulating layer INS2. The second insulating layer INS2 may be an inorganic insulating layer including an inorganic material, but the disclosure is not limited thereto.

The gate electrode GE may be disposed on the second insulating layer INS2. The gate electrode GE may overlap at least a portion is of the active layer ACT. The gate electrode GE may be insulated from the active layer ACT by the second insulating layer INS2.

A third insulating layer INS3 may be disposed on the gate electrode GE. For example, the third insulating layer INS3 may be an interlayer insulating layer. The third insulating layer INS3 may completely cover the gate electrode GE. Foer example, the gate electrode GE may be disposed between the second insulating layer INS2 and the third insulating layer INS3. The third insulating layer INS3 may be an inorganic insulating layer including an inorganic material, but the disclosure is not limited thereto.

The first transistor electrode TET1 and the second transistor electrode TET2 may be disposed on the third insulating layer INS3. The first transistor electrode TET1 and the second transistor electrode TET2 may be electrically connected to the active layer ACT. For example, the first transistor electrode TET1 and the second transistor electrode TET2 may electrically contact the first area and the second area of the active layer ACT through a contact hole passing through the second insulating layer INS2 and the third insulating layer INS3, respectively. According to an embodiment, the first transistor electrode TET1 or the second transistor electrode TET2 may be omitted, or may be formed integrally with the first area or the second area of the active layer ACT, respectively.

Any one of the first transistor electrode TET1 and the second transistor electrode TET2 may be electrically connected to the first pixel electrode AE1. For example, at least a portion of the first transistor electrode TET1 may extend toward the first emission area LA1, and may be electrically connected to the first pixel electrode AE1 through a contact hole CNT passing through the first insulating layer INS1, the second insulating layer INS2, and the third insulating layer INS3 or a connection member. Accordingly, the transistor T disposed in the first circuit area CA1 may be electrically connected to the first light emitting element LD1 and may is provide the driving signal for driving the first light emitting element LD1 to emit light.

Similarly to this, as shown in FIG. 14, in the second emission area LA2, a second pixel electrode AE2 may be disposed on the upper surface SUBa of the substrate SUB, and the common electrode CE may be disposed on the lower surface SUBb of the substrate SUB. The second pixel electrode AE2 may be disposed on the second light emitting element LD2 and may be electrically connected to a second surface LD2b of the second light emitting element LD2. The common electrode CE may be disposed on the second light emitting element LD2 and may be electrically connected to a first surface LD2a of the second light emitting element LD2. According to an embodiment, the second pixel electrode AE2 may electrically contact the second surface LD2b of the second light emitting element LD2, and the common electrode CE may electrically contact the first surface LD2a of the second light emitting element LD2.

In the third emission area LA3, a third pixel electrode AE3 may be disposed on the upper surface SUBa of the substrate SUB, and the common electrode CE may be disposed on the lower surface SUBb of the substrate SUB. The third pixel electrode AE3 may be disposed on the third light emitting element LD3 and may be electrically connected to a second surface LD3b of the third light emitting element LD3. The common electrode CE may be disposed on the third light emitting element LD3 and may be electrically connected to a first surface LD3a of the third light emitting element LD3. According to an embodiment, the third pixel electrode AE3 may electrically contact the second surface LD3b of the third light emitting element LD3, and the common electrode CE may electrically contact the first surface LD3a of the third light emitting element LD3.

According to an embodiment, the common electrode CE may be continuously disposed in the first direction DR1 on the lower surface SUBb of the substrate SUB, and may be electrically connected to the first is light emitting element LD1, the second light emitting element LD2, and the third light emitting element LD3. For example, the common electrode CE may provide a same signal (or voltage) to the first light emitting element LD1, the second light emitting element LD2, and the third light emitting element LD3.

For convenience of description, in FIG. 14, the first insulating layer INS1, the second insulating layer INS2, and the third insulating layer INS3 sequentially stacked on the upper surface SUBa of the substrate SUB are omitted.

As shown in FIG. 14, the first light emitting element LD1 of the first pixel PXL1 may include the first surface LD1a and the second surface LD1b that opposite to each other, and may include a side surface (or an outer circumferential surface) between the first surface LD1a and the second surface LD1b. A diameter Da1 of the first surface LD1a may be less than a diameter Db1 of the second surface LD1b. Accordingly, the side surface of the first light emitting element LD1 may form an angle with the first surface LD1a, and the angle may be an obtuse angle.

The first hole HL1 may include a first sidewall SW1 (or an inner circumferential surface) (or the substrate may include a first sidewall SW1), and the first sidewall SW1 may form an angle with respect to the lower surface SUBb (or a through surface) of the substrate SUB. The angle formed by the first sidewall SW1 and the lower surface SUBb of the substrate SUB may be the same as the angle formed by the side surface of the first light emitting element LD1. Accordingly, a shape of the first hole HL1 may be substantially the same as a shape of the first light emitting element LD1, and at least a portion of the side surface of the first light emitting element LD1 may contact the first sidewall SW1 of the first hole HL1.

The second light emitting element LD2 of the second pixel PXL2 may include the first surface LD2a and the second surface LD2b that opposite to each other, and may include a side surface (or an outer circumferential surface) between the first surface LD2a and the second surface LD2b. A diameter Da2 of the first surface LD2a may be less than a diameter Db2 of the second surface LD2b. Accordingly, the side surface of the second light emitting element LD2 may form an angle with the first surface LD2a, and the angle may be an obtuse angle.

The diameter Da2 of the first surface LD2a of the second light emitting element LD2 may be less than the diameter Da1 of the first surface LD1a of the first light emitting element LD1. The diameter Db2 of the second surface LD2b of the second light emitting element LD2 may be less than the diameter Db1 of the second surface LD1b of the first light emitting element LD1. According to an embodiment, the diameter Db2 of the second surface LD2b of the second light emitting element LD2 may be less than the diameter Da1 of the first surface LD1a of the first light emitting element LD1.

The second hole HL2 may include a second sidewall SW2 (or the substrate may include a second sidewall SW2), and the second sidewall SW2 may form an angle with respect to the lower surface SUBb (or a through surface) of the substrate SUB. The angle formed by the second sidewall SW2 and the lower surface SUBb of the substrate SUB may be the same as an angle formed by the side surface of the second light emitting element LD2. Accordingly, a shape of the second hole HL2 may be substantially the same as a shape of the second light emitting element LD2, and at least a portion of the side surface of the second light emitting element LD2 may contact the second sidewall SW2 of the second hole HL2.

The third light emitting element LD3 of the third pixel PXL3 may include the first surface LD3a and the second surface LD3b that opposite to each other, and may include a side surface (or an outer circumferential surface) between the first surface LD3a and the second surface LD3b. A diameter Da3 of the first surface LD3a may be less than a is diameter Db3 of the second surface LD3b. Accordingly, the side surface of the third light emitting element LD3 may form an angle with the first surface LD3a, and the angle may be an obtuse angle.

The diameter Da3 of the first surface LD3a of the third light emitting element LD3 may be less than the diameter Da2 of the first surface LD2a of the second light emitting element LD2. The diameter Db3 of the second surface LD3b of the third light emitting element LD3 may be less than the diameter Db2 of the second surface LD2b of the second light emitting element LD2. According to an embodiment, the diameter Db3 of the second surface LD3b of the third light emitting element LD3 may be less than the diameter Da2 of the first surface LD2a of the second light emitting element LD2.

The third hole HL3 may include a third sidewall SW3 (or the substrate may include a third sidewall SW3), and the third sidewall SW3 may form an angle with respect to the lower surface SUBb (or a through surface) of the substrate SUB. The angle formed by the third sidewall SW3 and the lower surface SUBb of the substrate SUB may be the same as an angle formed by the side surface of the third light emitting element LD3. Accordingly, a shape of the third hole HL3 may be substantially the same as a shape of the third light emitting element LD3, and at least a portion of the side surface of the third light emitting element LD3 may contact the third sidewall SW3 of the third hole HL3.

In an embodiment, the first sidewall SW1 of the first hole HL1, the second sidewall SW2 of the second hole HL2, and the third sidewall SW3 of the third hole HL3 may form the same angle with respect to the lower surface SUBb of the substrate SUB, but the disclosure is not limited thereto. In another embodiment, at least two sidewalls among the first sidewall SW1, the second sidewall SW2, and the third sidewall SW3 may form different angles with respect to the lower surface SUBb of the substrate SUB.

As shown in FIGS. 11 and 13, a channel wall CW may be is formed on the lower surface SUBb of the substrate SUB. The channel wall CW may be formed to extend in the first direction DR1. Multiple channel walls CW may be formed. The plurality of channel walls CW may be arranged in the second direction DR2.

The channel wall CW may not overlap the first emission area LA1, the second emission area LA2, and the third emission area LA3 in the third direction DR3. For example, the channel wall CW may not overlap the first hole HL1, the second hole HL2, and the third hole HL3 of the substrate SUB. According to an embodiment, at least a portion of the channel wall CW may overlap the first circuit area CA1, the second circuit area CA2, and the third circuit area CA3.

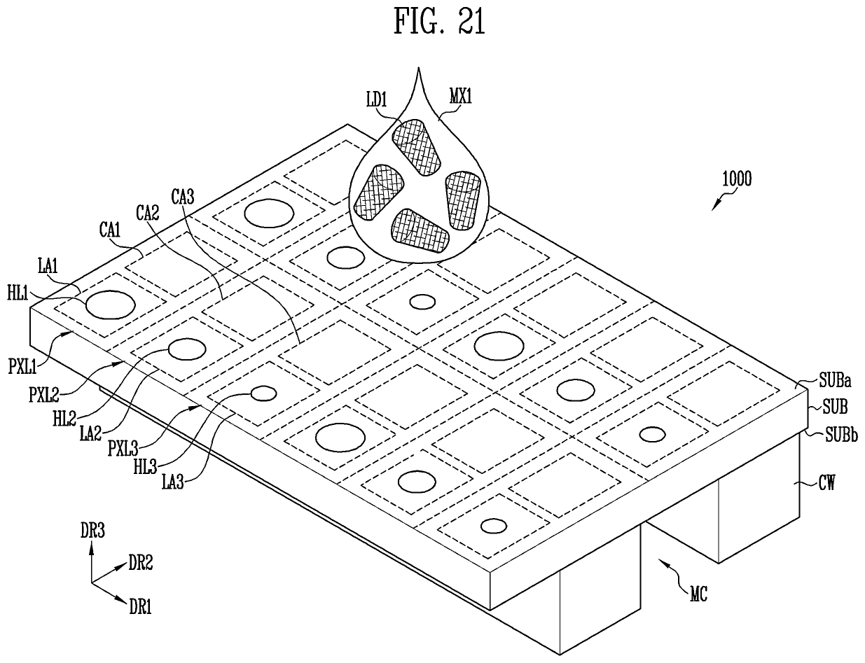

A micro channel MC may be formed between the plurality of channel walls CW. In a manufacturing process of the display device 1000, a fluid may flow through the micro channel MC. The pressure difference between the upper portion and the lower portion of the substrate SUB may be adjusted according to a state (for example, rate or the like) of the fluid flowing through the micro channel MC, and a lower side pressure of the substrate SUB may be adjusted to be lower than an upper side pressure of the substrate SUB so as to dispose the first light emitting element LD1, the second light emitting element LD2, and the third light emitting element LD3 on the substrate SUB. A method of disposing the first light emitting element LD1, the second light emitting element LD2, and the third light emitting element LD3 on the substrate SUB is described later with reference to FIGS. 21 to 27.

As described above, the light emitting elements LD1, LD2, and LD3 of each of the pixels PXL1, PXL2, and PXL3 may be disposed in the holes HL1, HL2, and HL3 of the substrate SUB, respectively. As the light emitting elements LD1, LD2, and LD3 are disposed in a vertical direction on the substrate SUB, an area in which the light emitting elements LD1, LD2, and LD3 is disposed may be widely secured, and thus it may be is advantageous in implementing a high-resolution display device. Since light emitted from the light emitting elements LD1, LD2, and LD3 may be directly emitted in the third direction DR3, the light output efficiency of the display device 1000 may be improved.

Hereinafter, other embodiments of the display device are described. In the following embodiment, the same components as those of the previously described embodiment are denoted by the same reference numerals, and a description thereof is omitted or simplified, and a different point is mainly described.

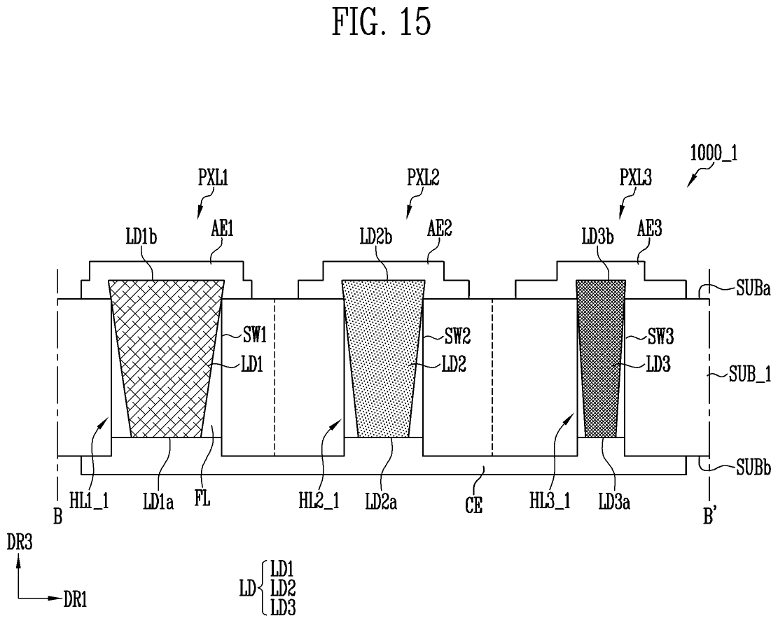

FIGS. 15 to 20 are schematic cross-sectional views of a display device according to various embodiments, and in particular, schematic cross-sectional views corresponding to line B-B′ of FIG. 12.

Referring to FIG. 15, the display device 1000_1 may include a substrate SUB_1, and a first pixel PXL1, a second pixel PXL2, and a third pixel PXL3 provided on the substrate SUB_1.

A first hole HL1_1, a second hole HL2_1, and a third hole HL3_1 passing through the substrate SUB_1 may be formed in the substrate SUB_1. The first hole HL1_1 may include a first sidewall SW1 (or an inner circumferential surface), and the first sidewall SW1 may be perpendicular to a lower surface SUBb of the substrate SUB_1. Similarly to the first hole HL1_1, the second hole HL2_1 and the third hole HL3_1 also may include a second sidewall SW2 and a third sidewall SW3 perpendicular to the lower surface SUBb of the substrate SUB_1, respectively.

A first light emitting element LD1 may be disposed in the first hole HL1_1. A diameter of a second surface LD1b of the first light emitting element LD1 may be greater than a diameter of the first hole HL1_1. Accordingly, the first light emitting element LD1 may not be completely inserted into the first hole HL1_1, and only a portion of the first light emitting element LD1 may be disposed in the first hole HL1_1. Another portion of the first light emitting element LD1 which is not disposed in the first hole HL1_1 may be exposed (or protruded) to an outside of the substrate SUB_1.

Similarly, a diameter of the second surface LD2b of the second light emitting element LD2 may be greater than a diameter of the second hole HL2_1. Accordingly, only a portion of the second light emitting element LD2 may be disposed in the second hole HL2_1, and another portion of the second light emitting element LD2 which is not disposed in the second hole HL2_1 may be exposed (or protruded) to the outside of the substrate SUB_1.

A diameter of a second surface LD3b of the third light emitting element LD3 may be greater than a diameter of the third hole HL3_1. Accordingly, only a portion of the third light emitting element LD3 may be disposed in the third hole HL3_1, and another portion of the third light emitting element LD3 which is not disposed in the third hole HL3_1 may be exposed (or protruded) to the outside of the substrate SUB_1.

A first pixel electrode AE1, a second pixel electrode AE2, and a third pixel electrode AE3 may be disposed on an upper surface SUBa of the substrate SUB_1, and a common electrode CE may be disposed on the lower surface SUBb of the substrate SUB_1.

Each of the first pixel electrode AE1, the second pixel electrode AE2, and the third pixel electrode AE3 may cover a portion of the light emitting element LD protruded to the outside of the substrate SUB_1 and may be formed in an approximately uniform thickness along surfaces of the substrate SUB_1 and the light emitting elements LD.

The common electrode CE may electrically contact first surfaces LD1a, LD2a, and LD3a of the respective first light emitting element LD1, second light emitting element LD2, and third light emitting element LD3. Since the light emitting elements LD are not completely inserted into the holes HL1_1, HL2_1, and HL3_1, the common electrode CE may fill a portion of the holes HL1_1, HL2_1, and HL3_1.

According to an embodiment, a filler FL filling an empty space between the light emitting elements LD and the sidewalls SW1, SW2, and SW3 of the holes HL1_1, HL2_1, HL3_1 may be further disposed, but the disclosure is not limited thereto. For example, an air layer may exist between the light emitting elements and the holes. The filler FL may be formed by including an organic material, but a material of the filler FL is not limited thereto.

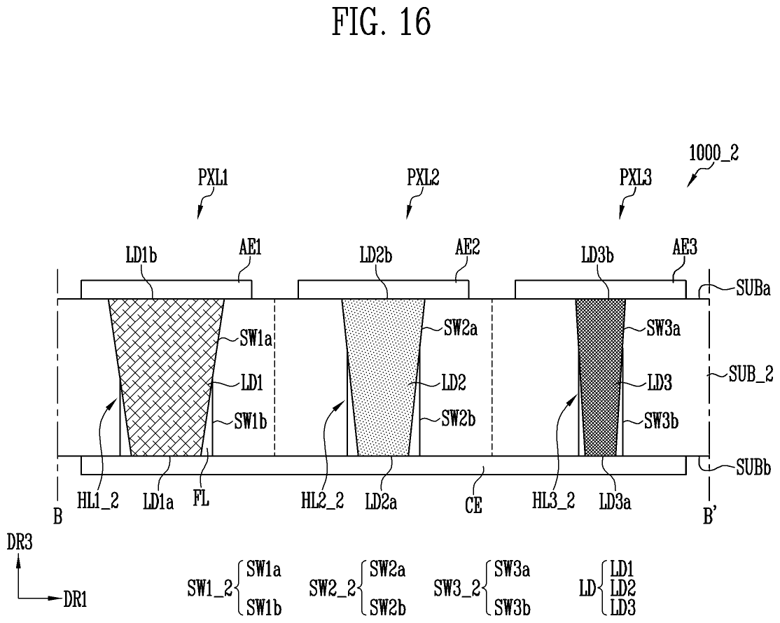

FIG. 16 is a schematic cross-sectional view of a display device taken along line B-B′ of FIG. 12 according to an embodiment. Referring to FIG. 16, the display device 1000_2 may include a substrate SUB_2, and a first pixel PXL1, a second pixel PXL2, and a third pixel PXL3 provided on the substrate SUB_2.

A first hole HL1_2, a second hole HL2_2, and a third hole HL3_2 passing through the substrate SUB_2 may be formed in the substrate SUB_2. The first hole HL1_2 may include a first sidewall SW1_2 (or an inner circumferential surface). The first sidewall SW1_2 may include an inclined surface SW1a having an angle with respect to a lower surface SUBb of the substrate SUB_2 and a vertical surface SW1b perpendicular to the lower surface SUBb of the substrate SUB_2.

Similarly to the first hole HL1_2, the second hole HL2_2 may include a second sidewall SW2_2 including an inclined surface SW2a and a vertical surface SW2b, and the third hole HL3_2 may include a third sidewall SW3_2 including an inclined surface SW3a and a vertical surface SW3b.

A first light emitting element LD1 may be disposed in the first hole HL1_2. According to an embodiment, a side surface of the first light emitting element LD1 may contact the inclined surface SW1a but may not contact the vertical surface SW1b.

Similarly to this, a second light emitting element LD2 may be disposed in the second hole HL2_2, and a side surface of the second light emitting element LD2 may contact the inclined surface SW2a but may not contact the vertical surface SW2b. A third light emitting element LD3 may be disposed in the third hole HL3_2, and a side surface of the third light emitting element LD3 may contact the inclined surface SW3a but may not the vertical surface SW3b.

Each of a first pixel electrode AE1, a second pixel electrode AE2, and a third pixel electrode AE3 may be disposed on an upper surface SUBa of the substrate SUB_2, and a common electrode CE may be disposed on the lower surface SUBb of the substrate SUB_2.

According to an embodiment, a filler FL filling an empty space between the light emitting elements LD and the sidewalls SW1_2, SW2_2, and SW3_2 of the holes HL1_2, HL2_2, and HL3_2 may be further disposed. The filler FL may be disposed between the light emitting element LD and the vertical surfaces SW1b, SW2b, and SW3b.

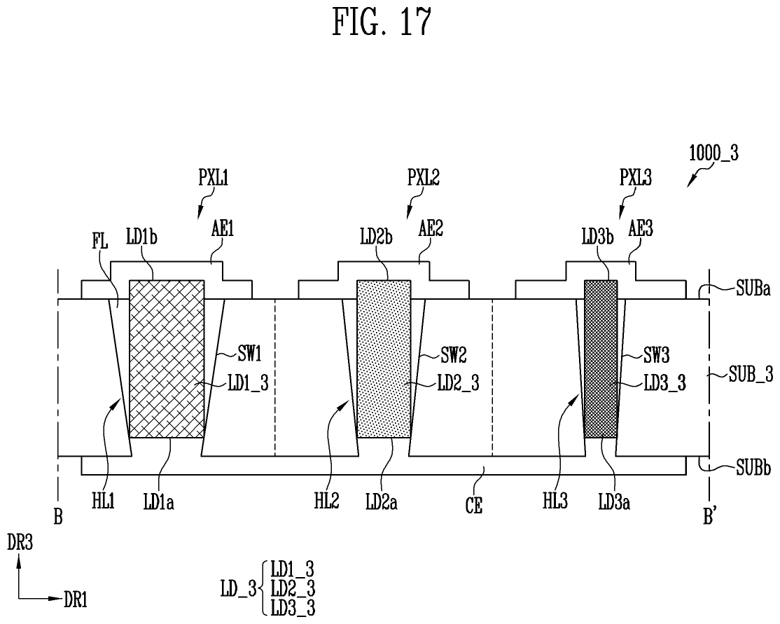

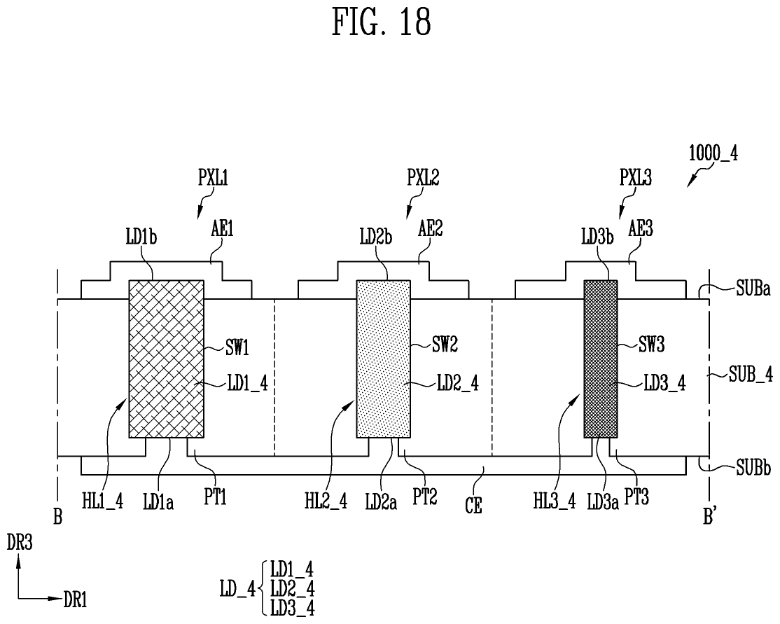

As described above, the light emitting element LD is not limited to the light emitting element LD of FIG. 6 of the truncated shape. In an embodiment of FIGS. 17 and 18, the light emitting element LD_3 may be the rod-shaped light emitting element LD of FIG. 1.

FIG. 17 is a schematic cross-sectional view of a display device taken along line B-B′ of FIG. 12 according to an embodiment. Referring to FIG. 17, the display device 1000_3 may include a substrate SUB, and a first pixel PXL1, a second pixel PXL2, and a third pixel PXL3 provided on the substrate SUB.

Each of the pixels PXL1, PXL2, and PXL3 may include a rod-shaped light emitting element LD_3. The first pixel PXL1 may include a first light emitting element LD1_3, the second pixel PXL2 may include a second light emitting element LD2_3, and the third pixel PXL3 may include a third light emitting element LD3_3.

A first hole HL1, a second hole HL2, and a third hole HL3 passing through the substrate SUB may be formed in the substrate SUB. The holes HL1, HL2, and HL3 may include sidewalls SW1, SW2, and SW3 having an angle with respect to a lower surface SUBb of the substrate SUB, respectively.

A first light emitting element LD1_3 may be disposed in the first hole HL1. A diameter of a first surface LD1a of the first light emitting element LD1_3 may be greater than a diameter of a lower through surface of the first hole HL1 (or a diameter of the first hole on the lower surface of the substrate). A diameter of a second surface LD1b of the first light emitting element LD1_3 may be less than a diameter of an upper through surface of the first hole HL1 (or a diameter of the first hole on the upper surface of the substrate). Accordingly, a portion of the first light emitting element LD1_3 may be disposed in the first hole HL1, and another portion of the first light emitting element LD1_3 may protrude to an outside of the substrate SUB.

Similarly to this, a second light emitting element LD2_3 may be disposed in the second hole HL2, and a third light emitting element LD3_3 may be disposed in the third hole HL3. A portion of the second light emitting element LD2_3 may be disposed in the second hole HL2 and, another portion of the second light emitting element LD2_3 may protrude to the outside of the substrate SUB. A portion of the third light emitting element LD3_3 may be disposed in the third hole HL3, and another portion of the third light emitting element LD3_3 may protrude to the outside of the substrate SUB.

A first pixel electrode AE1, a second pixel electrode AE2, and a third pixel electrode AE3 may be disposed on an upper surface SUBa of the substrate SUB, and a common electrode CE may be disposed on the lower surface SUBb of the substrate SUB.

Each of the first pixel electrode AE1, the second pixel electrode AE2, and the third pixel electrode AE3 may cover a portion of the light emitting element LD_3 protruding to the outside of the substrate SUB_3, and may be formed in an approximately uniform thickness along a surface is of the substrate SUB_3 and the light emitting elements LD_3.

The common electrode CE may be electrically connected to first surfaces LD1a, LD2a, and LD3a of the respective first light emitting element LD1_3, second light emitting element LD2_3, and third light emitting element LD3_3. According to an embodiment, the common electrode CE may electrically contact the first surfaces LD1a, LD2a, and LD3a. Since the light emitting elements LD_3 are not completely inserted into the holes HL1, HL2, and HL3, the common electrode CE may fill a portion of the holes HL1, HL2, and HL3.

According to an embodiment, a filler FL filling an empty space between the light emitting elements LD_3 and the sidewalls SW1, SW2, and SW3 of the holes HL1, HL2, and HL3 may be further disposed.

FIG. 18 is a schematic cross-sectional view of a display device taken along line B-B′ of FIG. 12 according to an embodiment. Referring to FIG. 18, the display device 1000_4 may include a substrate SUB_4, and a first pixel PXL1, a second pixel PXL2, and a third pixel PXL3 provided on the substrate SUB_4.

Each of the pixels PXL1, PXL2, and PXL3 may include a rod-shaped light emitting element LD_4. The first pixel PXL1 may include a first light emitting element LD1_4, the second pixel PXL2 may include a second light emitting element LD2_4, and the third pixel PXL3 may include a third light emitting element LD3_4.

A first hole HL1_4, a second hole HL2_4, and a third hole HL3_4 passing through the substrate SUB_4 may be formed in the substrate SUB_4. The holes HL1_4, HL2_4, and HL3_4 may include sidewalls SW1, SW2, and SW3 perpendicular to a lower surface SUBb of the substrate SUB_4, respectively. The substrate SUB_4 may further include protrusions PT1, PT2, and PT3 formed in the respective holes HL1_4, HL2_4, and HL3_4. The protrusions PT1, PT2, and PT3 may be formed on a side of the lower surface SUBb of the substrate SUB_4 and may protrude from the is respective sidewalls SW1, SW2, and SW3.

As an embodiment, the protrusions PT1, PT2, and PT3 may be a configuration formed integrally with the substrate SUB_4. For example, in a process of forming the holes HL1_4, HL2_4, and HL3_4 in the substrate SUB_4, the protrusions PT1, PT2, and PT3 may be a portion that is remained without being removed from the substrate SUB_4. However, the disclosure is not limited thereto, and in another embodiment, the protrusions PT1, PT2, and PT3 may be formed separately from the substrate SUB_4.

The first light emitting element LD1_4 may be disposed in the first hole HL1_4. The first protrusion PT1 may contact a portion of a first surface LD1a of the first light emitting element LD1_4. Another portion of the first surface LD1a of the first light emitting element LD1_4 which does not contact the first protrusion PT1 may be exposed to the outside. A portion of the first light emitting element LD1_4 including a second surface LD1b may be exposed to an outside of the substrate SUB_4.

The first protrusion PT1 may prevent the first light emitting element LD1_4 from being separated toward the lower surface SUBb of the substrate SUB_4 during a process of disposing the first light emitting element LD1_4 in the first hole HL1_4.

Similarly to this, the second light emitting element LD2_4 may be disposed in the second hole HL2_4, and the third light emitting element LD3_4 may be disposed in the third hole HL3_4. The second protrusion PT2 of the second hole HL2_4 may contact a portion of a first surface LD2a of the second light emitting element LD2_4, and the third protrusion PT3 of the third hole HL3_4 may contact a portion of a first surface LD3a of the third light emitting element LD3_4.

A first pixel electrode AE1, a second pixel electrode AE2, and a third pixel electrode AE3 may be disposed on an upper surface SUBa of the substrate SUB_4, and a common electrode CE may be disposed on the is lower surface SUBb of the substrate SUB_4.

Each of the first pixel electrode AE1, the second pixel electrode AE2, and the third pixel electrode AE3 may cover a portion of the light emitting element LD_4 protruding to the outside of the substrate SUB_4, and may be formed in an approximately uniform thickness along a surface of the substrate SUB_4 and the light emitting elements LD_4.

The common electrode CE may be electrically connected to first surfaces LD1a, LD2a, and LD3a of the respective first light emitting element LD1_4, second light emitting element LD2_4, and third light emitting element LD3_4. According to an embodiment, the common electrode CE may electrically contact the first surfaces LD1a, LD2a, and LD3a. Since the light emitting elements LD_4 are not completely inserted into the holes HL1_4, HL2_4 and HL3_4, the common electrode CE may fill a portion of the holes HL1_4, HL2_4, and HL3_4.

The above-described embodiments show a structure in which a thickness of the substrate and a length of the light emitting element are the same. However, the thickness of the substrate and the length of the light emitting element are not limited to that described above.

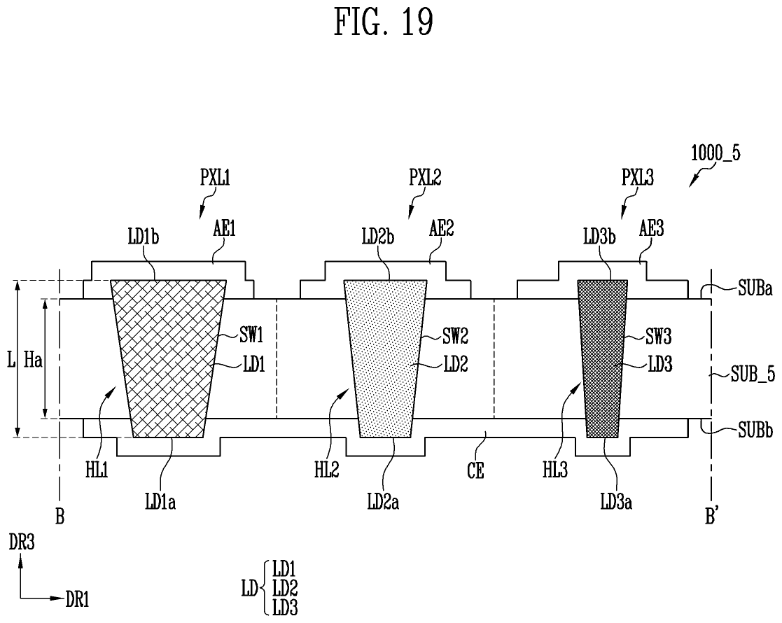

FIG. 19 is a schematic cross-sectional view of a display device taken along line B-B′ of FIG. 12 according to an embodiment. As an embodiment, as shown in FIG. 19, the display device 1000_5 may include a substrate SUB_5, and a first pixel PXL1, a second pixel PXL2, and a third pixel PXL3 provided on the substrate SUB_5. A thickness Ha of the substrate SUB_5 may be less than a length L of the light emitting element LD of each of the pixels PXL1, PXL2, and PXL3.

Accordingly, a portion of each of the light emitting elements LD may protrude to an outside of the substrate SUB_5. For example, a portion of a first light emitting element LD1 including a first surface LD1a and a portion of the first light emitting element LD1 including a second surface LD1b may protrude to the outside of the substrate SUB_5.

A first pixel electrode AE1, a second pixel electrode AE2, and a third pixel electrode AE3 may be disposed on an upper surface SUBa of the substrate SUB_5, and a common electrode CE may be disposed on a lower surface SUBb of the substrate SUB_5. Each of the first pixel electrode AE1, the second pixel electrode AE2, and the third pixel electrode AE3 may be disposed along an upper surface SUBa of the substrate SUB_5 and a surface of second surfaces LD1b, LD2b, and LD3b of the light emitting elements LD, and the common electrode CE may be continuously disposed along the lower surface SUBb of the substrate SUB_5 and a surface of first surfaces LD1a, LD2a, and LD3a of the light emitting element LD.

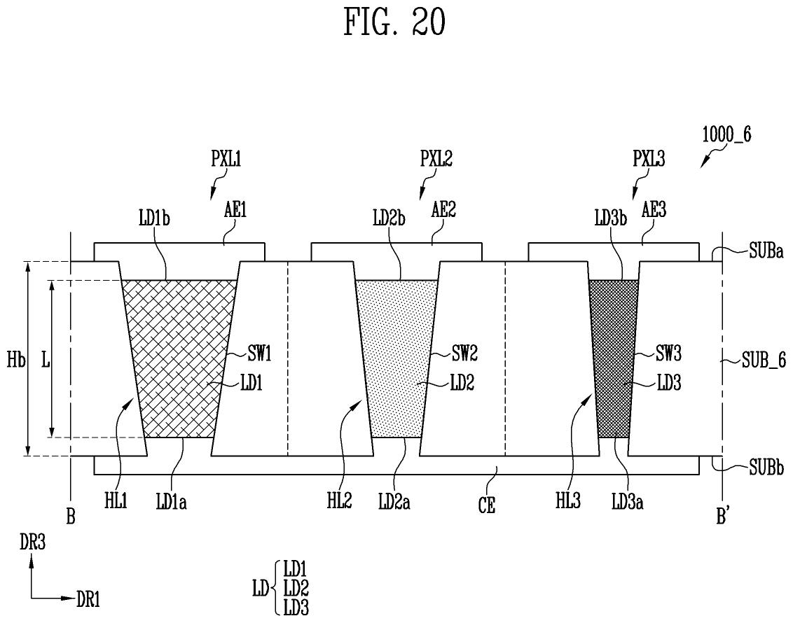

FIG. 20 is a schematic cross-sectional view of a display device taken along line B-B′ of FIG. 12 according to an embodiment. In another embodiment, as shown in FIG. 20, the display device 1000_6 may include a substrate SUB_6, and a first pixel PXL1, a second pixel PXL2, and a third pixel PXL3 provided on the substrate SUB_6. A thickness Hb of the substrate SUB_6 may be greater than a length L of a light emitting element LD of each of the pixels PXL1, PXL2, and PXL3.

Accordingly, each of the light emitting elements LD may be disposed inside the substrate SUB_6. For example, a first surface LD1a of the first light emitting element LD1 may be positioned upper (for example, in the third direction DR3) than a lower surface SUBb of the substrate SUB_6, and a second surface LD1b of the first light emitting element LD1 may be positioned lower (for example, in a direction opposite to the third direction DR3) than an upper surface SUBa of the substrate SUB_6.

A first pixel electrode AE1, a second pixel electrode AE2, and a third pixel electrode AE3 may be disposed on the upper surface SUBa of the substrate SUB_6, and a common electrode CE may be disposed on the lower surface SUBb of the substrate SUB_6. Each of the first pixel electrode AE1, the second pixel electrode AE2, and the third pixel electrode AE3 may be disposed along the upper surface SUBa of the substrate SUB_6 and a surface of second surfaces LD1b, LD2b, and LD3b of the light emitting elements LD and may fill a portion of each of the holes HL1, HL2, and HL3. The common electrode CE may be continuously disposed along the lower surface SUBb of the substrate SUB_6 and a surface of first surfaces LD1a, LD2a, and LD3a of the light emitting element LD, and may fill a portion of the holes HL1, HL2, and HL3.

FIGS. 21 to 27 are perspective views and schematic cross-sectional views sequentially illustrating a method of manufacturing a display device according to an embodiment of the disclosure. For example, FIGS. 21 to 27 illustrate a method of manufacturing the display device illustrated in FIGS. 11 to 14.

A method of manufacturing a display device according to an embodiment is sequentially described with further reference to FIGS. 21 to 27 in conjunction with the embodiment described in FIGS. 11 to 14.

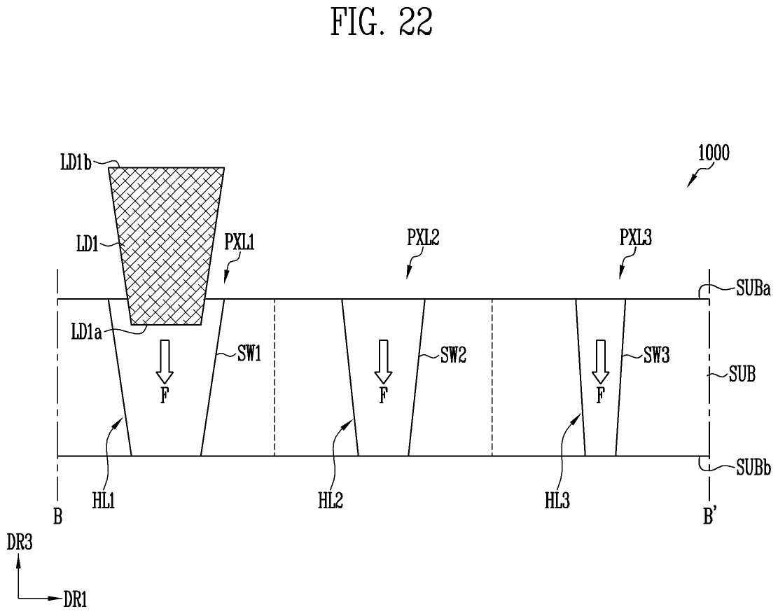

First, as shown in FIGS. 21 and 22, a first mixed liquid MX1 including the first light emitting element LD1 may be provided on the substrate SUB.

The substrate SUB may include the first hole HL1 formed in the first emission area LA1, the second hole HL2 formed in the second emission area LA2, and the third hole HL3 formed in the third emission area LA3. The first hole HL1, the second hole HL2, and the third hole HL3 may pass through the substrate SUB.

The first mixed liquid MX1 may be entirely dispersed on the upper surface SUBa of the substrate SUB. The shape of the first hole HL1 formed in the substrate SUB may be the same as the shape of the first light emitting element LD1. For example, the diameter of the first hole HL1 may be substantially the same as the diameter of the first light emitting element LD1. Sizes of the second hole HL2 and the third hole HL3 formed in the substrate SUB may be less than that of the first light emitting element LD1.

After dispersing the first mixed liquid MX1 on the substrate is SUB, in order to dispose and fix the first light emitting element LD1 in the first hole HL1, an upper side pressure of the substrate SUB and a lower side pressure of the substrate SUB may be adjusted. For example, the upper side pressure (or a first pressure) of the substrate SUB may be adjusted to be greater than the lower side pressure (or a second pressure) of the substrate SUB.

In order to adjust the lower side pressure of the substrate SUB to be low, the channel wall CW formed under the substrate SUB and the micro channel MC formed between the channel walls CW may be used. For example, the lower side pressure of the substrate SUB may be adjusted to be lower by flowing a fluid through the micro channel MC at a high rate. Accordingly, a pressure difference F may occur between an upper portion and a lower portion of the substrate SUB, and the first light emitting element LD1 may be inserted into the first hole HL1 of the substrate SUB and may be vertically aligned by the pressure difference F.

As described above, the size (or the diameter) of the first light emitting element LD1 may be greater than the size (or the diameter) of the second hole HL2 formed in the substrate SUB and the size (or the diameter) of the third hole HL3, and the first light emitting element LD1 may not be inserted into the second hole HL2 and the third hole HL3. Accordingly, the first light emitting element LD1 may be disposed at a desired position (for example, the first hole HL1).

Areas (or diameters) of the first surface LD1a and the second surface LD1b of the first light emitting element LD1 may be different from each other. For example, the diameter of the first surface LD1a of the first light emitting element LD1 may be less than the diameter of the second surface LD1b of the first light emitting element LD1. Accordingly, in case that the first light emitting element LD1 is inserted from the second surface LD1b in a process in which the first light emitting element LD1 is inserted into the first hole HL1, the diameter of the first hole HL1 may be gradually is decreased from the upper surface SUBa to the lower surface SUBb of the substrate SUB, and the first light emitting element LD1 may not be normally inserted into the first hole HL1. For example, as the shapes of the first light emitting element LD1 and the first hole HL1 are formed to be vertically asymmetric, a direction in which the first light emitting element LD1 is disposed and fixed may be determined. For example, the first surface LD1a of the first light emitting element LD1 may be disposed on the side of the lower surface SUBb of the substrate SUB, and the second surface LD1b of the first light emitting element LD1 may be disposed on a side of the upper surface SUBa of the substrate SUB.

After disposing the first light emitting element LD1 in the first hole HL1, the first mixed liquid MX1 may be removed from the substrate SUB. In a process of removing the first mixed liquid MX1, the first light emitting elements LD1 which are not disposed in the first hole HL1 or incorrectly disposed in the second hole HL2 or the third hole HL3 may be recovered. The recovered first light emitting element LD1 may be reused in a process of manufacturing another display device, and manufacturing cost of the display device may be reduced.

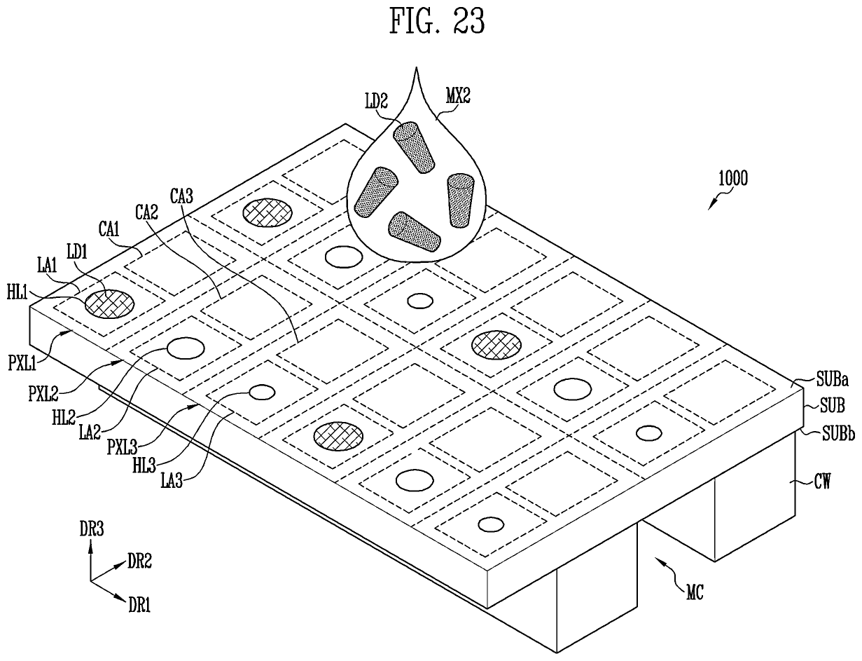

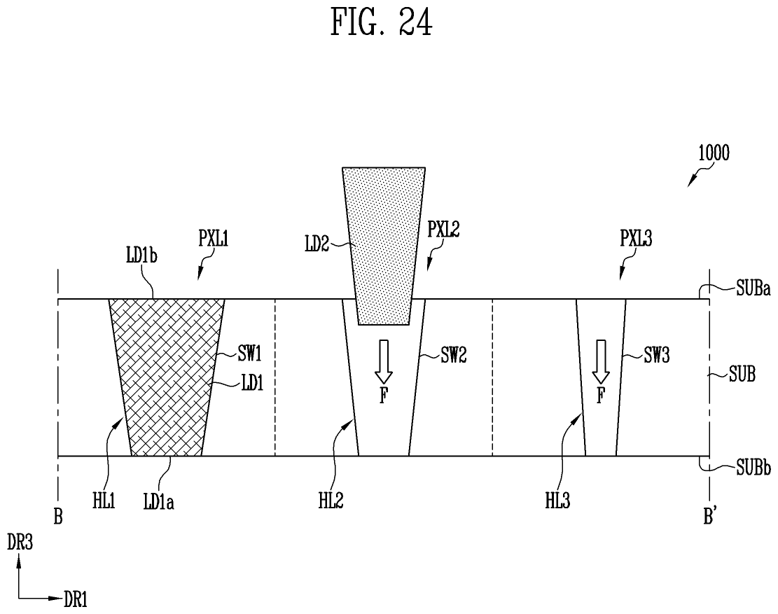

As shown in FIGS. 23 and 24, a second mixed liquid MX2 including the second light emitting element LD2 may be provided on the substrate SUB.

The second mixed liquid MX2 may be entirely dispersed on the upper surface SUBa of the substrate SUB. The shape of the second hole HL2 formed in the substrate SUB may be the same as the shape of the second light emitting element LD2. For example, the diameter of the second hole HL2 may be substantially the same as the diameter of the second light emitting element LD2. The size of the third hole HL3 formed in the substrate SUB may be less than that of the second light emitting element LD2.

After dispersing the second mixed liquid MX2 on the substrate is SUB, the upper side pressure of the substrate SUB and the lower side pressure of the substrate SUB may be adjusted, and the upper side pressure (or the first pressure) of the substrate SUB may be adjusted to be greater than the lower side pressure (or the second pressure) of the substrate SUB, in order to dispose and fix the second light emitting element LD2 in the second hole HL2. The second light emitting element LD2 may be inserted into the second hole HL2 of the substrate SUB and may be vertically aligned by the pressure difference F between the upper portion and the lower portion of the substrate SUB.

As described above, since the first light emitting element LD1 is disposed in the first hole HL1, the second light emitting element LD2 may not be disposed in the first hole HL1. The size (or the diameter) of the second light emitting element LD2 may be greater than the size (or the diameter) of the third hole HL3 formed in the substrate SUB, and the second light emitting element LD2 may not be inserted into the third hole HL3. Accordingly, the second light emitting element LD2 may be disposed at a desired position (for example, the second hole HL2).

Similarly to the first light emitting element LD1, a diameter of the first surface LD2a of the second light emitting element LD2 may be less than a diameter of the second surface LD2b of the second light emitting element LD2. As shapes of the second light emitting element LD2 and the second hole HL2 are formed to be vertically asymmetric, a direction in which the second light emitting element LD2 is disposed and fixed may be determined. For example, the first surface LD2a of the second light emitting element LD2 may be disposed on the side of the lower surface SUBb of the substrate SUB, and the second surface LD2b of the second light emitting element LD2 may be disposed on the side of the upper surface SUBa of the substrate SUB.

After the second light emitting element LD2 is disposed in the second hole HL2, the second mixed liquid MX2 may be removed from the is substrate SUB. In a process of removing the second mixed liquid MX2, the second light emitting elements LD2 which are not disposed in the second hole HL2 or incorrectly disposed in the third hole HL3 may be recovered. The recovered second light emitting element LD2 may be reused in a process of manufacturing another display device.

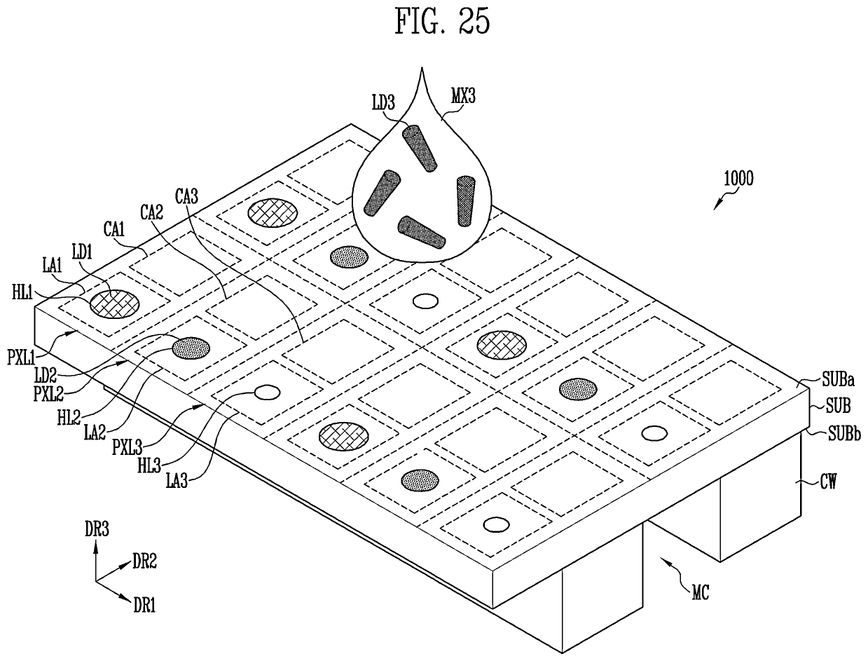

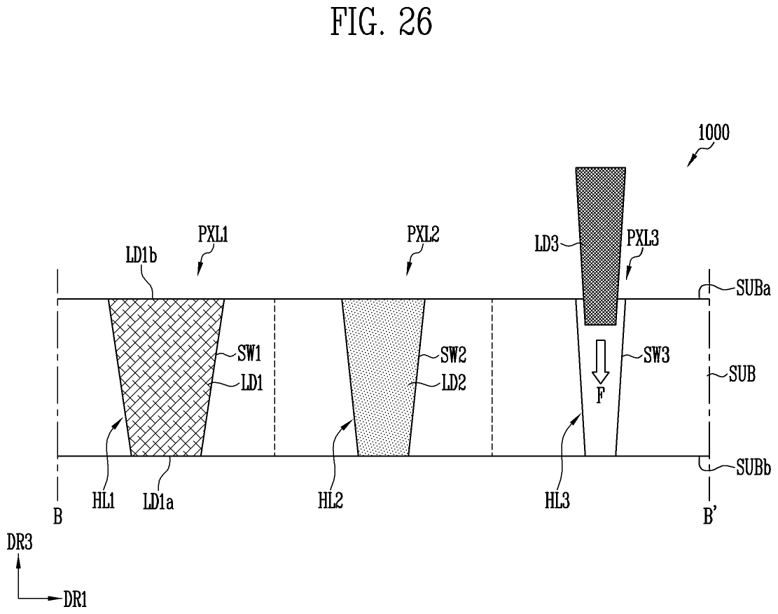

As shown in FIGS. 25 and 26, a third mixed liquid MX3 including the third light emitting element LD3 may be provided on the substrate SUB.

The third mixed liquid MX3 may be entirely dispersed on the upper surface SUBa of the substrate SUB. The shape of the third hole HL3 formed in the substrate SUB may be the same as the shape of the third light emitting element LD3. For example, the diameter of the third hole HL3 may be substantially the same as the diameter of the third light emitting element LD3.

After dispersing the third mixed liquid MX3 on the substrate SUB, the upper side pressure of the substrate SUB and the lower side pressure of the substrate SUB may be adjusted, and the upper side pressure (or the first pressure) of the substrate SUB may be adjusted to be greater than the lower side pressure (or the second pressure) of the substrate SUB, in order to dispose and fix the third light emitting element LD3 in the third hole HL3. The third light emitting element LD3 may be inserted into the third hole HL3 of the substrate SUB and may be vertically aligned by the pressure difference F between the upper portion and the lower portion of the substrate SUB

As described above, since the first light emitting element LD1 is disposed in the first hole HL1 and the second light emitting element LD2 is disposed in the second hole HL2, the third light emitting element LD3 may not be disposed in the first hole HL1 and the second hole HL2. Accordingly, the third light emitting element LD3 may be disposed at a desired position (for example, the third hole HL3).

Similarly to the first light emitting element LD1 and the second light emitting element LD2, the diameter of the first surface LD3a of the third light emitting element LD3 may be less than the diameter of the second surface LD3b of the third light emitting element LD3. As the shapes of the third light emitting element LD3 and the third hole HL3 are formed to be vertically asymmetric, a direction in which the third light emitting element LD3 is disposed and fixed may be determined. For example, the first surface LD3a of the third light emitting element LD3 may be disposed on the side of the lower surface SUBb of the substrate SUB, and the second surface LD3b of the third light emitting element LD3 may be disposed on the side of the upper surface SUBa of the substrate SUB.

After the third light emitting element LD3 is disposed in the third hole HL3, the third mixed liquid MX3 may be removed from the substrate SUB. In a process of removing the third mixed liquid MX3, the third light emitting elements LD3 which are not disposed in the third hole HL3 may be recovered. The recovered third light emitting element LD3 may be reused in a process of manufacturing another display device.

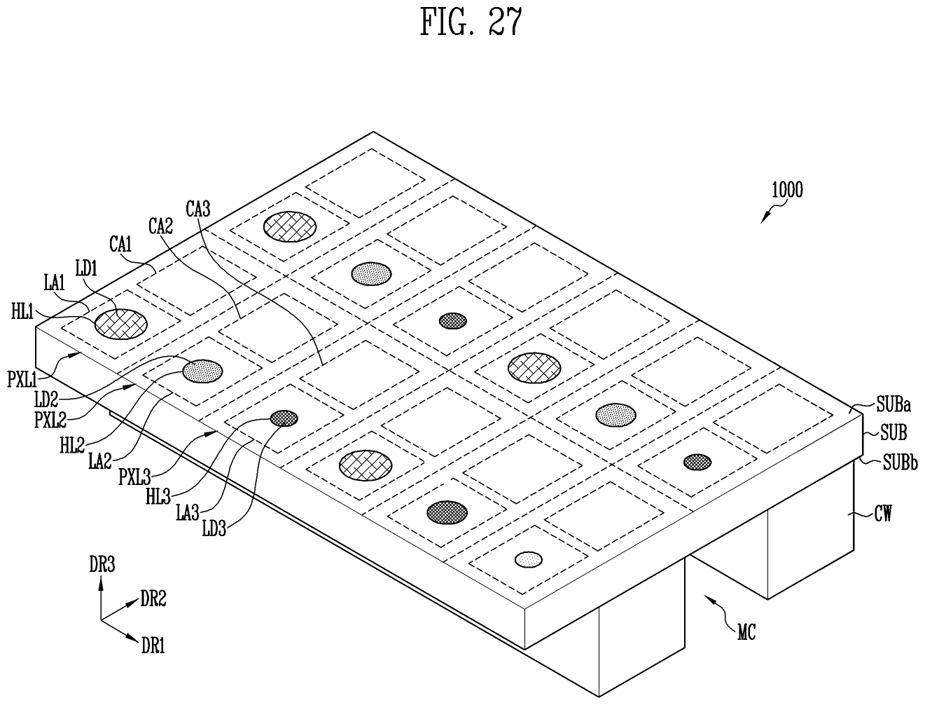

Thereafter, as shown in FIG. 27, the first light emitting element LD1, the second light emitting element LD2, and the third light emitting element LD3 may be disposed and fixed in the first hole HL1, the second hole HL2, and the third hole HL3 formed in the substrate SUB, respectively.

Similarly to the display device 1000 of FIGS. 13 and 14, the first pixel electrode AE1 electrically connected to the first light emitting element LD1, the second pixel electrode AE2 electrically connected to the second light emitting element LD2, and the third pixel electrode AE3 electrically connected to the third light emitting element LD3 may be formed on the upper surface SUBa of the substrate SUB, and the common electrode CE commonly electrically connected to the first light emitting element LD1, the second light emitting element LD2, and the third light emitting element is LD3 may be formed on the lower surface SUBb of the substrate SUB. The pixel electrodes AE1, AE2, and AE3 and the common electrode CE may provide a driving signal to each of the light emitting elements LD1, LD2, and LD3, and the light emitting elements LD1, LD2, and LD3 may emit light of a luminance corresponding to the provided driving signal.

As described above, the pixel electrodes AE1, AE2, and AE3 may include a transparent conductive material, and may include, for example, indium tin oxide (ITO), indium zinc oxide (IZO), zinc oxide (ZnO), indium tin zinc oxide (ITZO), and the like. Accordingly, among the light emitted from the light emitting elements LD1, LD2, and LD3, light proceeding in the third direction DR3 may pass through the pixel electrodes AE1, AE2, and AE3 and may be emitted to the outside.

The common electrode CE may include a conductive material having a constant reflectance, and may include, for example, a metal such as Al, Mg, Ag, Pt, Pd, Au, Ni, Nd, Ir, Cr, Ti, and an alloy thereof, and the like. Accordingly, among the light emitted from the light emitting elements LD1, LD2, and LD3, light proceeding in the direction opposite to the third direction DR3 may be reflected in the third direction DR3 by the common electrode CE and may be emitted to the outside.

According to the method of manufacturing the display device according to the embodiment, since the light emitting elements LD1, LD2, and LD3 may be aligned and fixed in the first hole HL1, the second hole HL2, and the third hole HL3, which are formed in the substrate SUB, in the vertical direction, an area in which the light emitting elements LD1, LD2, and LD3 may be disposed may be widely secured, and a high-resolution display device may be implemented.

Since the light emitting elements LD1, LD2, and LD3 are fixed to the substrate SUB according to the pressure difference between the upper portion and the lower portion of the substrate SUB, the light emitting elements LD1, LD2, and LD3 may be fixed strongly compared to fixing by is electric force, and a separate fixing member for fixing the light emitting elements LD1, LD2, and LD3 may be omitted. Accordingly, alignment accuracy of the light emitting elements LD1, LD2, and LD3 and reliability of the display device may be improved.

Since the sizes of the light emitting elements LD1, LD2, and LD3 and the sizes of the holes HL1, HL2, and HL3 are adjusted to be different from each other, the light emitting elements LD1, LD2, and LD3 may be disposed at desired positions. As the light emitting elements LD1, LD2, and LD3 are formed in a vertical asymmetric shape, a direction in which the light emitting elements LD1, LD2, and LD3 are aligned may be controlled.

As described above, since the light emitting elements LD1, LD2, and LD3 which are not aligned in a process of aligning the light emitting elements LD1, LD2, and LD3 may be recovered and reused, the manufacturing cost of the display device may be reduced.

Although the embodiments of the disclosure have been described with reference to the accompanying drawings, it will be understood by those skilled in the art to which the disclosure pertains that the embodiments may be implemented in other specific forms without changing the technical scope and essential features of the disclosure. Therefore, it should be understood that the embodiments described above are illustrative and are not restrictive in all aspects.

1. A display device comprising:
a substrate including a first emission area; and
a first light emitting element disposed on the substrate and emitting light of a first color, wherein
the substrate further includes a first hole passing through the substrate in the first emission area, and
at least a portion of the first light emitting element is disposed in the first hole.

2. The display device according to claim 1, wherein the first light emitting element includes a first surface and a second surface opposite to each other,
the first surface is disposed adjacent to a lower surface of the substrate,
the second surface is disposed adjacent to an upper surface of the substrate, and
an aspect ratio of the first light emitting element is greater than 1.

3. The display device according to claim 2, wherein a diameter of the second surface is greater than a diameter of the first surface, and
the first light emitting element further includes a side surface disposed between the first surface and the second surface.

4. The display device according to claim 3, wherein the side surface of the first light emitting element contacts an inner circumferential surface of the first hole.

5. The display device according to claim 3, wherein the substrate includes a sidewall in the first hole, the sidewall being perpendicular to the lower surface of the substrate,
a diameter of the first hole is greater than the diameter of the first surface,
the diameter of the first hole is less than the diameter of the second surface, and
a portion of the first light emitting element protrudes to an outside of the substrate.

6. The display device according to claim 5, further comprising:
a filler filling a space between the sidewall and the first light emitting element.

7. The display device according to claim 3, wherein
the substrate includes a sidewall in the first hole,
the sidewall includes a vertical surface perpendicular to the lower surface of the substrate and an inclined surface having an angle with respect to the lower surface of the substrate,
the side surface of the first light emitting element contacts the inclined surface, and
the side surface of the first light emitting element does not contact the vertical surface.

8. The display device according to claim 2, wherein a diameter of the first surface and a diameter of the second surface are the same in a plan view.

9. The display device according to claim 8, wherein
the substrate includes a sidewall in the first hole, the sidewall having an angle with respect to the lower surface of the substrate,
a diameter of the first light emitting element is greater than a diameter of the first hole on the lower surface of the substrate,
the diameter of the first light emitting element is less than a diameter of the first hole on the upper surface of the substrate, and
a portion of the first light emitting element protrudes to an outside of the substrate.

10. The display device according to claim 9, further comprising:
a filler filling a space between the sidewall and the first light emitting element.

11. The display device according to claim 8, wherein
the substrate includes a sidewall in the first hole, the sidewall being perpendicular to the lower surface of the substrate,
the substrate further includes a protrusion protruding from the sidewall and integral with the substrate,
the protrusion contacts a portion of the first surface, and
the protrusion exposes another portion of the first surface.

12. The display device according to claim 2, wherein a thickness of the substrate is less than a length of the first light emitting element, and a portion of the first light emitting element protrudes to an outside of the substrate.

13. The display device according to claim 2, wherein a thickness of the substrate is greater than a length of the first light emitting element, and the first light emitting element is disposed in the first hole of the substrate.

14. The display device according to claim 2, further comprising:
a common electrode disposed on the lower surface of the substrate and electrically connected to the first surface of the first light emitting element; and
a pixel electrode disposed on the upper surface of the substrate and electrically connected to the second surface of the first light emitting element.

15. The display device according to claim 14, wherein
the substrate further includes a first circuit area disposed adjacent to the first emission area,
the display device further comprises a transistor disposed on the upper surface of the substrate in the first circuit area, and
the transistor is electrically connected to the pixel electrode.

16. The display device according to claim 2, further comprising:
a second light emitting element emitting light of a second color different from the first color, wherein
the substrate further includes:
a second emission area disposed adjacent to the first emission area, and
a second hole passing through the substrate in the second emission area,
a diameter of the second hole is less than a diameter of the first hole, and
at least a portion of the second light emitting element is disposed in the second hole.

17. The display device according to claim 16, wherein a diameter of the second light emitting element is less than a diameter of the first light emitting element.

18. The display device according to claim 16, wherein
the second light emitting element includes a first surface and a second surface facing each other, and
the display device further comprising:
a common electrode disposed on the lower surface of the substrate and electrically connected to the first surface of the first light emitting element and the first surface of the second light emitting element;
a first pixel electrode disposed on the upper surface of the substrate and electrically connected to the second surface of the first light emitting element; and
a second pixel electrode disposed on the upper surface of the substrate and electrically connected to the second surface of the second light emitting element.

19. The display device according to claim 1, further comprising:
a plurality of channel walls disposed on a lower surface of the substrate,
wherein the plurality of channel walls do not overlap the first hole in a plan view.

20. A method of manufacturing a display device, comprising:
preparing a substrate including a first hole passing through the substrate;
providing a first mixed liquid including a first light emitting element emitting light of a first color on the substrate; and
vertically aligning the first light emitting element in the first hole by setting a first pressure of an upper portion of the substrate to be higher than a second pressure of a lower portion of the substrate.

21. The method according to claim 20, wherein the first light emitting element includes a first surface and a second surface opposite to each other, and
an aspect ratio of the first light emitting element is greater than 1.

22. The method according to claim 21, wherein a diameter of the first surface is less than a diameter of the second surface, and
in the vertically aligning of the first light emitting elements,
the first surface is disposed adjacent to a lower surface of the substrate, and
the second surface is disposed adjacent to an upper surface of the substrate.

23. The method according to claim 20, wherein the substrate further includes a second hole passing through the substrate,
the method further comprises:
providing a second mixed liquid including a second light emitting element emitting light of a second color different from the first color on the substrate; and
vertically aligning the second light emitting element in the second hole by setting the first pressure to be higher than the second pressure,
wherein a diameter of the second hole is less than a diameter of the first hole, and
a diameter of the second light emitting element is less than a diameter of the first light emitting element.

24. The method according to claim 23, wherein the substrate further includes a third hole passing through the substrate,
the method further comprises:
providing a third mixed liquid including a third light emitting element emitting light of a third color different from the first color and the second color on the substrate; and
vertically aligning the third light emitting element in the third hole by setting the first pressure to be higher than the second pressure,
wherein a diameter of the third hole is less than the diameter of the first hole and the diameter of the second hole, and
a diameter of the third light emitting element is less than the diameter of the first light emitting element and the diameter of the second light emitting element.

25. The method according to claim 23, further comprising:
disposing a common electrode electrically connected to the first light emitting element and the second light emitting element on a lower surface of the substrate;
disposing a first pixel electrode electrically connected to the first light emitting element on an upper surface of the substrate; and
disposing a second pixel electrode electrically connected to the second light emitting element on the upper surface of the substrate.
